(19) United States
(12) Patent Application Publication
(10) Pub. No.: US 2026/0017428 A1
(43) Pub. Date: Jan. 15, 2026

(54) METHODS AND SYSTEMS FOR ENHANCED ASSESSMENT AND SCORING OF HIGH-PERFORMANCE COMPUTE ARCHITECTURES

(71) Applicant: Penguin Computing, Inc., Fremont, CA (US)

(72) Inventors: Kevin Manalo, Saint Johns, FL (US); Nicholas McCollum, Decatur, AL (US); Mark Seamans, San Diego, CA (US); Sharri Parsell, Portland, OR (US)

(73) Assignee: Penguin Computing, Inc., Fremont, CA (US)

(21) Appl. No.: 19/255,625

(22) Filed: Jun. 30, 2025

Related U.S. Application Data
(60) Provisional application No. 63/670,432, filed on Jul. 12, 2024.

(51) Int. Cl. G06F 30/20

(52) U.S. Cl. CPC G06F 30/20

(57) ABSTRACT

A system, method, and computer-program product includes obtaining a set of compute architecture design parameters associated with a target subscriber, generating a HPC architecture data object for the target subscriber that satisfies the set of compute architecture design parameters, executing, in real-time or near real-time, one or more automated pairwise assessments between the HPC architecture data object generated for the target subscriber and a reference HPC architecture data object, computing, in real-time or near real-time, a percent of potential value that indicates a degree of performance disparity between the HPC architecture data object generated for the target subscriber and the reference HPC architecture data object based on pairwise assessment findings outputted by the one or more automated pairwise assessments, and constructing, for the target subscriber, an optimal HPC environment corresponding to the HPC architecture data object when the percent of potential value satisfies a predetermined minimum score threshold value.

### CROSS-REFERENCE TO RELATED APPLICATIONS

This application claims the benefit of U.S. Provisional Application No. 63/670,432, filed 12 Jul. 2024, which is incorporated in its entirety by this reference.

### TECHNICAL FIELD

This invention relates generally to the computer management field, and more specifically to new and useful systems and methods for evaluating and scoring compute architectures in the computer management field.

### BACKGROUND

Traditionally, assessing and optimizing high-performance compute architectures, including AI compute architectures, is a time-consuming process that requires a high level of specialized knowledge in high-performance computing (HPC) development and design. This time-consuming process fails to scale effectively to meet the growing computational demands of modern applications and workloads.

Furthermore, this process lacks explainability, making it difficult for subscribers to understand how their compute architecture impacts performance. Therefore, there is a need in the art to accelerate the assessment and optimization of high-performance compute architectures, while also providing greater explainability to help subscribers understand the impact of their architecture choices. The embodiments of the present application provide technical solutions that address, at least, the needs described above, as well as the deficiencies in the state of the art.

### BRIEF SUMMARY OF THE EMBODIMENTS

In one embodiment, a computer-implemented method for real-time generation and performance optimization of high-performance computing (HPC) architectures includes at a compute architecture optimization service implemented by a distributed network of computers: obtaining, via a graphical user interface, a set of compute architecture design parameters associated with a target subscriber, wherein the set of compute architecture design parameters include: one or more distinct types of artificial intelligence (AI) compute tasks the target subscriber intends to execute within a HPC environment, and a set of compute architecture design constraints specifying one or more immutable boundaries for controlling a compute architecture design space used by the compute architecture optimization service; generating, by the distributed network of computers, a HPC architecture data object for the target subscriber that satisfies the set of compute architecture design parameters obtained via the graphical user interface, wherein generating the HPC architecture data object includes: translating the set of compute architecture design parameters into a set of hardware components and a set of software components that are (i) collectively capable of supporting execution of the one or more distinct types of AI compute tasks and (ii) reside within the compute architecture design space formed according to the set of compute architecture design constraints, and in response to generating the HPC architecture data object for the target subscriber: executing, in real-time or near real-time by the distributed network of computers, one or more automated pairwise assessments between the HPC architecture data object generated for the target subscriber and a reference HPC architecture data object; computing, in real-time or near real-time by the distributed network of computers, a percent of potential score that indicates a degree of performance disparity between the HPC architecture data object generated for the target subscriber and the reference HPC architecture data object based on pairwise assessment findings outputted by the one or more automated pairwise assessments; and constructing, in the real-world, an optimal HPC environment for the target subscriber that corresponds to the HPC architecture data object when the percent of potential score satisfies a predetermined minimum score threshold value.

In one embodiment, at least one of the one or more automated pairwise assessments detects that a first compute architecture deviation exists between the HPC architecture data object generated for the target subscriber and the reference HPC architecture data object, the computer-implemented method further includes automatically retrieving, using the distributed network of computers, a performance degradation factor that corresponds to the first compute architecture deviation in response to querying a performance degradation repository using the first compute architecture deviation as a query parameter, and the percent of potential score is computed by deducting the performance degradation factor that corresponds to the first compute architecture deviation from a service-default percent of potential score attributed to the reference HPC architecture data object.

In one embodiment, the one or more automated pairwise assessments detect that a plurality of compute architecture deviations exist between the HPC architecture data object generated for the target subscriber and the reference HPC architecture data object, the computer-implemented method further includes automatically retrieving, using the distributed network of computers, a respective performance degradation factor that corresponds to each compute architecture deviation of the plurality of compute architecture deviations in response to querying a performance degradation repository using the plurality of compute architecture deviations as query parameters, and the percent of potential score is computed for the HPC architecture data object by deducting the respective performance degradation factor that corresponds to each compute architecture deviation of the plurality of compute architecture deviations from a service-default percent of potential score attributed to the reference HPC architecture data object.

In one embodiment, the computer-implemented method further includes displaying, via the graphical user interface, a plurality of selectable normalization factors, wherein each selectable normalization factor of the plurality of selectable normalization factors corresponds to a distinct performance criterion for assessing the HPC architecture data object generated for the target subscriber relative to the reference HPC architecture data object; receiving, via the graphical user interface, a user input selecting a selectable bandwidth normalization factor of the plurality of selectable normalization factors; and in response to receiving the user input selecting the selectable bandwidth normalization factor displayed on the graphical user interface, automatically computing an additional percent of potential score for the HPC architecture data object generated for the target subscriber based on assessing a maximum bandwidth capacity of the HPC architecture data object against a maximum bandwidth capacity of the reference HPC architecture data object.

In one embodiment, the computer-implemented method further includes displaying, via the graphical user interface, a plurality of selectable normalization factors, wherein each selectable normalization factor of the plurality of selectable normalization factors corresponds to a distinct architecture performance assessment criterion; detecting, via the graphical user interface, a sequence of one or more user inputs selecting each of the plurality of selectable normalization factors displayed on the graphical user interface; and in response to detecting the sequence of the one or more user inputs, simultaneously computing, in parallel, a respective normalized percent of potential score for each of the plurality of selectable normalization factors selected using the graphical user interface, wherein each respective normalized percent of potential score is computed based on the distinct architecture performance assessment criterion of a respective selectable normalization factor of the plurality of selectable normalization factors for which that respective normalized percent of potential score corresponds.

In one embodiment, the percent of potential score computed for the HPC architecture data object does not satisfy the predetermined minimum score threshold value, the computer-implemented method further includes in response to detecting the percent of potential score computed for the HPC architecture data object does not satisfy the predetermined minimum score threshold value: providing the HPC architecture data object generated for the target subscriber and the reference HPC architecture data object as input to a machine learning model; predicting, using the machine learning model, one or more percent of potential improvement recommendations for the HPC architecture data object based on the machine learning model assessing the HPC architecture data object generated for the target subscriber and the reference HPC architecture data object; adapting the HPC architecture data object generated for the target subscriber to an adapted HPC architecture data object based on the one or more percent of potential improvement recommendations predicted by the machine learning model; computing, in real-time or near real-time by the distributed network of computers, a second percent of potential score for the adapted HPC architecture data object indicating a degree of performance disparity between the adapted HPC architecture data object and the reference HPC architecture data object, wherein the second percent of potential score computed for the adapted HPC architecture data object satisfies the predetermined minimum score threshold value; and constructing, in the real-world, an optimal HPC environment for the target subscriber corresponding to the adapted HPC architecture data object based on the second percent of potential score satisfying the predetermined minimum score threshold value.

In one embodiment, the one or more percent of potential improvement recommendations include a first percent of potential improvement recommendation that textually indicates replacing an ethernet-based networking configuration specified by the HPC architecture data object with an InfiniBand-based networking configuration, a second percent of potential improvement recommendation that textually indicates updating a firmware version associated with one or more hardware components specified by the HPC architecture data object to a current firmware version or at least a more recent firmware version than the firmware version currently specified by the HPC architecture data object, a third percent of potential improvement recommendation that textually indicates increasing a total number of compute nodes specified by the HPC architecture data object to a greater quantity of compute nodes than currently specified by the HPC architecture data object, and a fourth percent of potential improvement recommendation that textually indicates replacing a first type of graphics processing unit (GPU) specified by the HPC architecture data object with a different GPU type.

In one embodiment, the HPC architecture data object generated for the target subscriber includes a structured representation of a subscriber-specific compute architecture, the reference HPC architecture data object includes a structured representation of a reference compute architecture, and the computer-implemented method further includes: displaying, via the graphical user interface, a graphical representation of the subscriber-specific compute architecture; displaying, via the graphical user interface, a graphical representation of the reference compute architecture; and displaying, via the graphical user interface, the percent of potential score between the graphical representation of the subscriber-specific compute architecture and the graphical representation of the reference compute architecture, wherein the graphical representation of the subscriber-specific compute architecture is spatially separated from the graphical representation of the reference compute architecture.

In one embodiment, executing the one or more automated pairwise assessments include: assessing a maximum bandwidth capacity of the HPC architecture data object against a maximum bandwidth capacity of the reference HPC architecture data object, assessing a total number of computing nodes included in the HPC architecture data object against a total number of computing nodes included in the reference HPC architecture data object, assessing a backend networking infrastructure of the HPC architecture data object against a backend networking infrastructure of the reference HPC architecture data object, assessing a type of graphics processing units included in the HPC architecture data object against a type of graphics processing units included in the reference HPC architecture data object, and assessing a network latency profile of the HPC architecture data object against a network latency profile of the reference HPC architecture data object.

In one embodiment, generating the HPC architecture data object for the target subscriber further includes instantiating, by the distributed network of computers, a data model based on a compute architecture schema provided by the compute architecture optimization service in response to translating the set of compute architecture design parameters into the set of hardware components and the set of software components, and encoding, by the distributed network of computers, the data model to include the set of hardware components and the set of software components.

In one embodiment, the percent of potential score satisfies the predetermined minimum score threshold value, and constructing the optimal HPC environment for the target subscriber includes: physically installing a plurality of computing nodes specified by the HPC architecture data object at a target real-world location or a target physical location, wherein each computing node of the plurality of computing nodes includes a plurality of graphics processing units (GPUs) and a plurality of central processing units (CPUs), and physically connecting the plurality of computing nodes together using a plurality of physical networking components as specified by the HPC architecture data object.

In one embodiment, the computer-implemented method further includes before computing the percent of potential score that indicates the degree of performance disparity between the HPC architecture data object generated for the target subscriber and the reference HPC architecture data object: computing a plurality of normalized percent of potential scores that collectively assess the HPC architecture data object and the reference HPC architecture data object across multiple distinct performance dimensions, and computing a composite percent of potential score based on a combination of the plurality of normalized percent of potential scores, wherein the composite percent of potential score is used as the percent of potential score that indicates the degree of performance disparity between the HPC architecture data object and the reference HPC architecture data object.

In one embodiment, the compute architecture optimization service includes a plurality of predetermined reference HPC architecture data objects, the computer-implemented method further includes before executing the one or more automated pairwise assessments: detecting, via the graphical user interface, an input from a user selecting a target one of the plurality of predetermined reference HPC architecture data objects that corresponds to the reference HPC architecture data object, and in response to detecting the input from the user selecting the target one of the plurality of predetermined reference HPC architecture data objects, automatically commencing the one or more automated pairwise assessments.

In one embodiment, the compute architecture optimization service automatically elects the reference HPC architecture data object to be assessed against the HPC architecture data object, and in response to the compute architecture optimization service automatically electing the reference HPC architecture data object, automatically commencing the one or more automated pairwise assessments.

In one embodiment, a computer-program product comprising a non-transitory machine-readable storage medium storing computer instructions that, when executed by one or more processors, perform operations including at a compute architecture optimization service: obtaining, via a graphical user interface, a set of compute architecture design parameters associated with a target subscriber, wherein the set of compute architecture design parameters include: one or more distinct types of artificial intelligence (AI) compute tasks the target subscriber intends to execute within a HPC environment, and a set of compute architecture design constraints specifying one or more immutable boundaries for controlling a compute architecture design space used by the compute architecture optimization service; generating, by the one or more processors, a HPC architecture data object for the target subscriber that satisfies the set of compute architecture design parameters obtained via the graphical user interface, wherein generating the HPC architecture data object includes: translating the set of compute architecture design parameters into a set of hardware components and a set of software components that are (i) collectively capable of supporting execution of the one or more distinct types of AI compute tasks and (ii) reside within the compute architecture design space formed according to the set of compute architecture design constraints, and in response to generating the HPC architecture data object for the target subscriber: executing, in real-time or near real-time by the one or more processors, one or more automated pairwise assessments between the HPC architecture data object generated for the target subscriber and a reference HPC architecture data object; computing, in real-time or near real-time by the one or more processors, a percent of potential score that indicates a degree of performance disparity between the HPC architecture data object generated for the target subscriber and the reference HPC architecture data object based on pairwise assessment findings outputted by the one or more automated pairwise assessments; and constructing, in the real-world, an optimal HPC environment corresponding to the HPC architecture data object when the percent of potential score satisfies a predetermined minimum score threshold value.

In one embodiment, the computer instructions, when executed by the one or more processors, perform operations further comprising automatically generating a plurality of percent of potential score improvement recommendations for the HPC architecture data object, wherein each percent of potential score improvement recommendation of the plurality of percent of potential score improvement recommendations includes a proposed modification to one or more hardware components or software components specified by the HPC architecture data object; displaying, via the graphical user interface, the plurality of percent of potential score improvement recommendations in association with a graphical representation of the HPC architecture data object generated for the target subscriber and a graphical representation of the reference HPC architecture data object, detecting an input selecting one of the plurality of percent of potential score improvement recommendations, and in response to detecting the input selecting the one of the plurality of percent of potential score improvement recommendations, automatically adapting the graphical representation of the HPC architecture data object displayed on the graphical user interface to include the proposed modification that corresponds to the one of the plurality of percent of potential score improvement recommendations.

In one embodiment, the computer instructions, when executed by the one or more processors, perform operations further comprising automatically generating a plurality of percent of potential score improvement recommendations for the HPC architecture data object, wherein each percent of potential score improvement recommendation of the plurality of percent of potential score improvement recommendations includes a proposed modification to one or more hardware components or software components specified by the HPC architecture data object; displaying, via the graphical user interface, the plurality of percent of potential score improvement recommendations in association with a graphical representation of the HPC architecture data object generated for the target subscriber and a graphical representation of the reference HPC architecture data object, detecting an input selecting one of the plurality of percent of potential score improvement recommendations, and in response to detecting the input selecting the one of the plurality of percent of potential score improvement recommendations: automatically scrolling or automatically navigating within the graphical representation of the HPC architecture data object to a portion of the graphical representation of the HPC architecture data object that corresponds to the proposed modification specified by the one of the plurality of percent of potential score improvement recommendations.

In one embodiment, the computer instructions, when executed by the one or more processors, perform operations further comprising: detecting, during the execution of the one or more automated pairwise assessments, a plurality of compute architecture deviations between the HPC architecture data object generated for the target subscriber and the reference HPC architecture data object; attributing a corresponding performance degradation factor to each compute architecture deviation of the plurality of compute architecture deviations; and displaying, via the graphical user interface, a data table that includes the plurality of compute architecture deviations in association with their respective corresponding performance degradation factor.

In one embodiment, the computer instructions, when executed by the one or more processors, perform operations further comprising: displaying, via the graphical user interface, a graphical representation of the HPC architecture data object; automatically generating, for each compute architecture deviation of the plurality of compute architecture deviations, a corresponding graphical marker within the graphical representation of the HPC architecture data object; detecting a user input selecting the corresponding graphical marker associated with a first compute architecture deviation of the plurality of compute architecture deviations, wherein a user interface position of the corresponding graphical marker associated with the first compute architecture deviation within the graphical representation of the HPC architecture data object corresponds to a location of a hardware or software component of the HPC architecture data object contributing to the first compute architecture deviation; and in response to detecting the user input selecting the corresponding graphical marker associated with the first compute architecture deviation, instantiating, via the graphical user interface, a popover user interface object that includes a natural language description of the first compute architecture deviation, the corresponding performance degradation factor attributed to the first compute architecture deviation, and one or more recommended compute architectural modifications to resolve the first compute architecture deviation.

In one embodiment, a computer-implemented system including: one or more processors; a memory; a computer-readable medium operably coupled to the one or more processors, the computer-readable medium having computer-readable instructions stored thereon that, when executed by the one or more processors, cause a computing device to perform operations comprising: at a compute architecture optimization service: obtaining, via a graphical user interface, a set of compute architecture design parameters associated with a target subscriber, wherein the set of compute architecture design parameters include: one or more distinct types of artificial intelligence (AI) compute tasks the target subscriber intends to execute within a HPC environment, and a set of compute architecture design constraints specifying one or more immutable boundaries for controlling a compute architecture design space used by the compute architecture optimization service; generating, by the one or more processors, a HPC architecture data object for the target subscriber that satisfies the set of compute architecture design parameters obtained via the graphical user interface, wherein generating the HPC architecture data object includes: translating the set of compute architecture design parameters into a set of hardware components and a set of software components that are (i) collectively capable of supporting execution of the one or more distinct types of AI compute tasks and (ii) reside within the compute architecture design space formed according to the set of compute architecture design constraints, and in response to generating the HPC architecture data object for the target subscriber: executing, in real-time or near real-time by the one or more processors, one or more automated pairwise assessments between the HPC architecture data object generated for the target subscriber and a reference HPC architecture data object; computing, in real-time or near real-time by the one or more processors, a percent of potential score for the HPC architecture data object that indicates a degree of performance disparity between the HPC architecture data object generated for the target subscriber and the reference HPC architecture data object based on pairwise assessment findings outputted by the one or more automated pairwise assessments; and constructing, in the physical world, an optimal HPC environment corresponding to the HPC architecture data object when the percent of potential score satisfies a predetermined minimum score threshold value.

In one embodiment, a computer-implemented method for real-time generation and performance optimization of high-performance computing (HPC) architectures includes at a compute architecture optimization service implemented by a distributed network of computers: obtaining, via a graphical user interface, a set of compute architecture design parameters associated with a target subscriber, wherein the set of compute architecture design parameters include: one or more distinct types of artificial intelligence (AI) compute tasks the target subscriber intends to execute within a HPC environment, and a set of compute architecture design constraints specifying one or more immutable boundaries for controlling a compute architecture design space used by the compute architecture optimization service; generating, by the distributed network of computers, a HPC architecture data object for the target subscriber that satisfies the set of compute architecture design parameters obtained via the graphical user interface, wherein generating the HPC architecture data object includes: translating the set of compute architecture design parameters into a set of hardware components and a set of software components that are (i) collectively capable of supporting execution of the one or more distinct types of AI compute tasks and (ii) reside within the compute architecture design space formed according to the set of compute architecture design constraints, and in response to generating the HPC architecture data object for the target subscriber: executing, in real-time or near real-time by the distributed network of computers, one or more automated pairwise assessments between the HPC architecture data object generated for the target subscriber and a reference HPC architecture data object; computing, in real-time or near real-time by the distributed network of computers, a percent of potential value that indicates a likely degree of computing performance disparity between the HPC architecture data object generated for the target subscriber and the reference HPC architecture data object based on pairwise assessment findings outputted by the one or more automated pairwise assessments; and constructing, in the real-world, an optimal HPC environment for the target subscriber that: improves a likely computing performance, when executing the one or more distinct types of AI compute tasks, by implementing the optimal HPC environment in lieu of a non-optimized HPC environment of a non-optimized HPC architecture data object, and homologously corresponds to the HPC architecture data object when the percent of potential value satisfies a predetermined minimum score threshold value. It shall be recognized that in some embodiments, an HPC architecture data object may be a non-optimized HPC architecture data object when a respective percent of potential value computed for the HPC architecture data object does not satisfy the predetermined minimum score threshold value. In other words, in some embodiments, a HPC architecture data object having an associated percent of potential value below the predetermined minimum score threshold value may be determined to be a non-optimized HPC architecture data object.

In one embodiment, the percent of potential value computed for the HPC architecture data object does not satisfy the predetermined minimum score threshold value, the computer-implemented method further includes: in response to detecting the percent of potential value computed for the HPC architecture data object does not satisfy the predetermined minimum score threshold value: providing the HPC architecture data object generated for the target subscriber and the reference HPC architecture data object as input to a machine learning model; predicting, using the machine learning model, one or more percent of potential improvement recommendations for the HPC architecture data object based on the machine learning model assessing the HPC architecture data object generated for the target subscriber and the reference HPC architecture data object; adapting the HPC architecture data object generated for the target subscriber to an adapted HPC architecture data object based on the one or more percent of potential improvement recommendations predicted by the machine learning model; computing, in real-time or near real-time by the distributed network of computers, a second percent of potential value for the adapted HPC architecture data object indicating a degree of performance disparity between the adapted HPC architecture data object and the reference HPC architecture data object, wherein the second percent of potential value computed for the adapted HPC architecture data object satisfies the predetermined minimum score threshold value; and constructing, in the real-world, an optimal HPC environment for the target subscriber corresponding to the adapted HPC architecture data object based on the second percent of potential value satisfying the predetermined minimum score threshold value, wherein the optimal HPC environment for the target subscriber corresponding to the adapted HPC architecture data is constructed in lieu of a compute environment homologously corresponding to the HPC architecture data object generated for the target subscriber.

In one embodiment, the percent of potential value computed for the HPC architecture data object does not satisfy the predetermined minimum score threshold value, the computer-implemented method further includes: in response to detecting the percent of potential value computed for the HPC architecture data object does not satisfy the predetermined minimum score threshold value: providing the HPC architecture data object generated for the target subscriber and the reference HPC architecture data object as input to a machine learning model; predicting, using the machine learning model, one or more percent of potential improvement recommendations for the HPC architecture data object based on the machine learning model assessing the HPC architecture data object generated for the target subscriber and the reference HPC architecture data object; adapting the HPC architecture data object generated for the target subscriber to an adapted HPC architecture data object based on the one or more percent of potential improvement recommendations predicted by the machine learning model; computing, in real-time or near real-time by the distributed network of computers, a second percent of potential value for the adapted HPC architecture data object indicating a degree of computing performance disparity between the adapted HPC architecture data object and the reference HPC architecture data object, wherein the second percent of potential value computed for the adapted HPC architecture data object satisfies the predetermined minimum score threshold value; and constructing, in the real-world, an optimal HPC environment corresponding to the adapted HPC architecture data object for the target subscriber based on the second percent of potential value satisfying the predetermined minimum score threshold value, wherein the optimal HPC environment corresponding to the adapted HPC architecture data is constructed in lieu of a compute environment homologously corresponding to the HPC architecture data object generated for the target subscriber.

### BRIEF DESCRIPTION OF THE FIGURES

FIG. 1 illustrates a schematic representation of a system in accordance with one or more embodiments of the present application;

FIG. 1A illustrates a schematic representation of a subsystem of the system in accordance with one or more embodiments of the present application;

FIG. 2 illustrates an example method in accordance with one or more embodiments of the present application;

FIG. 3 illustrates an example of a subscriber-specific compute architecture in accordance with one or more embodiments of the present application;

FIG. 4 illustrates an example of a reference compute architecture in accordance with one or more embodiments of the present application;

FIG. 5 illustrates an example schematic for generating or designing a subscriber-specific compute architecture in accordance with one or more embodiments of the present application;

FIG. 6 illustrates an example of computing a percent of potential score for a subscriber-specific compute architecture in accordance with one or more embodiments of the present application;

FIG. 7 illustrates another example of computing a percent of potential score for a subscriber-specific compute architecture in accordance with one or more embodiments of the present application; and

FIGS. 8-12 illustrate example graphical user interfaces in accordance with one or more embodiments of the present application.

### DESCRIPTION OF THE PREFERRED EMBODIMENTS

The following description of the preferred embodiments of the invention is not intended to limit the invention to these preferred embodiments, but rather to enable any person skilled in the art to make and use this invention.

The systems, methods, computer-program products, and apparatuses described herein may be used across a broad range of high-performance computing (HPC) infrastructure design and performance optimization applications. In particular, some of the systems, methods, computer-program products, and apparatuses may function to compute a percent of potential (POP) score that quantifies a degree of performance disparity between a subscriber-specific compute architecture (e.g., a HPC architecture data object generated for the target subscriber) and a reference compute architecture (e.g., a reference HPC architecture data object). As described in more detail herein, computing the POP score for the subscriber-specific compute architecture (e.g., the HPC architecture data object generated for the target subscriber) provides many technical benefits and advantages.

Traditional systems and methods are ill-equipped for assessing compute architectures accurately. This is due to the inherently complex and highly interdependent nature of modern high-performance computing environments, where diverse hardware components and software components interact in ways that can significantly affect overall compute performance and compute efficiency. As a result, such traditional systems and methods are unable to explain how specific architecture design choices and configurations contribute to compute performance limitations, nor can such traditional systems and methods provide recommendations for improving compute performance (e.g., mitigating compute performance bottlenecks, etc.) associated with a proposed subscriber-specific compute architecture (e.g., a proposed HPC architecture data object generated for the target subscriber).

Conversely, the systems, methods, computer-program products, and apparatuses described herein enable compute architecture explainability by intuitively surfacing how specific compute architecture design choices and configurations contribute to detected compute performance limitations, thereby enabling users and/or subscribers to understand, trace, and address root causes of compute architecture inefficiencies. For instance, some of the systems, methods, computer-program products, and apparatuses described herein may function to compute a POP score for a subscriber-specific compute architecture (e.g., a HPC architecture data object generated for the target subscriber or the like) and generate interactive user interface (UI) explainability artifacts that visually and/or textually identify which compute architecture components of the subscriber-specific compute architecture are responsible for reductions in compute performance relative to a reference compute architecture (e.g., a target reference HPC architecture data object). Therefore, unlike traditional systems and methods that offer no transparency or explainability of compute architectures, the embodiments described herein provide an improvement over traditional systems and methods by at least automatically detecting performance-limiting architectural components within a target compute architecture, computing a POP score of the target compute architecture based on the detected performance-limiting architectural components, and generating interactive UI objects that textually or graphically explain the compute architecture components responsible for performance degradation and how each respective compute architecture component contributes to the computed POP score.

Another technical advantage of the systems, methods, computer-program products, and apparatuses described herein includes the ability to iteratively adapt a subscriber-specific compute architecture until the POP score computed for the subscriber-specific compute architecture satisfies a predetermined minimum score threshold value. In some embodiments, each iterative adaptation of the subscriber-specific compute architecture may be performed automatically by a computer-implemented system or service, manually by a user, or a combination thereof. In one or more embodiments, after each distinct iteration or adaptation of the subscriber-specific compute architecture, the system or service described herein may automatically compute, in real-time or near real-time, a POP score to detect whether the new iteration of the subscriber-specific compute architecture, as modified, meets or exceeds the predetermined minimum score threshold value. Once the POP score for a respective iteration or adaptation satisfies the predetermined minimum score threshold value, the subscriber-specific compute architecture corresponding to the POP score that satisfies the predetermined minimum score threshold value may be used to construct a real-world high-performance computing environment, thereby ensuring that an optimized HPC environment is constructed.

It shall be recognized that, in some embodiments, constructing the real-world high-performance computing environment may include deploying and/or configuring both hardware and software components specified by the subscriber-specific compute architecture satisfying the predetermined minimum PoP score threshold value. The hardware components, in some embodiments, may include, but are not limited to, compute nodes, GPUs, CPUs, memory modules, storage systems, interconnects, switches, power delivery units, and cooling infrastructure (e.g., thermal management systems, heat dissipation devices, etc.). The software components, in some embodiments, may include, but are not limited to, orchestration services, runtime schedulers, firmware configurations, and workload execution controls that may control how the underlying hardware components operate. It shall be recognized that, in some embodiments, the constructed high-performance computing environment may correspond directly to the subscriber-specific compute architecture that satisfied the predetermined minimum score threshold value, such that each hardware component specified by the subscriber-specific compute architecture is physically installed or deployed at a target physical location and each software component of the subscriber-specific compute architecture is programmatically configured or installed to operate in coordination with the physically installed or deployed hardware components.

As a result, the systems, methods, computer-program products, and apparatuses described herein provide an improvement over traditional systems and methods by increasing computing resource efficiency, improving compute resource utilization, and enhancing workload throughput. In particular, by constructing the high-performance computing environment in accordance with a respective subscriber-specific compute architecture that satisfies the predetermined minimum score threshold value, the embodiments described herein reduce the likelihood of overprovisioned, underutilized, or misconfigured compute resources within a physically constructed, real-world high-performance computing environment.

Another technical benefit of the systems, methods, computer-program products, and apparatuses described herein includes the ability to construct and iteratively refine a subscriber-specific compute architecture using a graphical user interface. Conventional systems do not provide mechanisms for interactively assembling, modifying, or visualizing component-level architectural configurations in a performance-aware manner. Conversely, the systems, methods, computer-program products, and apparatuses described herein enable users to construct the subscriber-specific compute architecture through interactive graphical user interfaces, as described in more detail herein. The graphical user interfaces described herein may include performance-guided input mechanisms that allow the user to define or modify hardware and software components of the subscriber-specific compute architecture while simultaneously exposing how such modifications affect the POP score relative to a reference compute architecture. Therefore, the systems, methods, computer-program products, and apparatuses described herein provide an improvement over conventional systems by enabling low-friction, performance-informed construction of compute architectures through an input-efficient graphical interface.

It shall be further recognized that, in some embodiments, the graphical user interfaces described herein may further enable intuitive exploration of detected compute architecture deviations. For example, once a subscriber-specific compute architecture is constructed or modified, the system or service may surface visual and/or textual indicators that identify specific architectural components contributing to reductions in the computed POP score relative to a reference compute architecture. In some embodiments, these deviations may be presented as interactive elements within the graphical user interface, allowing the user to explore, isolate, and iteratively refine underperforming components of the subscriber-specific compute architecture in a guided manner. Therefore, the systems, methods, computer-program products, and apparatuses described herein provide an improvement over conventional systems by enabling not only the low-friction construction and refinement of compute architectures, but also the intuitive identification and exploration of performance-limiting deviations within the subscriber-specific compute architecture itself.

Accordingly, the systems, methods, computer-program products, and apparatuses described herein provide an improvement over traditional systems and methods by enabling faster construction of a respective subscriber-specific compute architecture, reducing the total number of user inputs needed to generate a respective subscriber-specific compute architecture, reducing the total number of user inputs needed to adapt or modify a respective subscriber-specific compute architecture, and/or reducing the total amount of time for which a graphical user interface must remain instantiated to iterate upon and/or generate a respective subscriber-specific compute architecture. It shall be recognized that, in some embodiments, the longer the graphical user interface is instantiated on a computing device-particularly a computing device powered by a battery (e.g., battery-powered computing device)—the more processing resources (e.g., CPU cycles, memory usage, I/O operations, etc.) are consumed, which in turn increases power draw and accelerates battery depletion. Accordingly, reducing the number of user inputs and shortening the duration of graphical user interface instantiation provides an improvement over traditional systems by minimizing compute resource utilization and preserving battery longevity during compute architecture design tasks. In other words, reducing the number of user inputs and the amount of time the graphical user interface is instantiated improves the utilization of underlying resources of the computing device (e.g., less CPU usage, less memory usage, fewer user interface rendering operations, reduced input/output activity, and diminished power draw), thereby improving system efficiency, responsiveness, and overall resource utilization during compute architecture construction and refinement tasks.

### 1. System for Enhanced Cluster Health Management

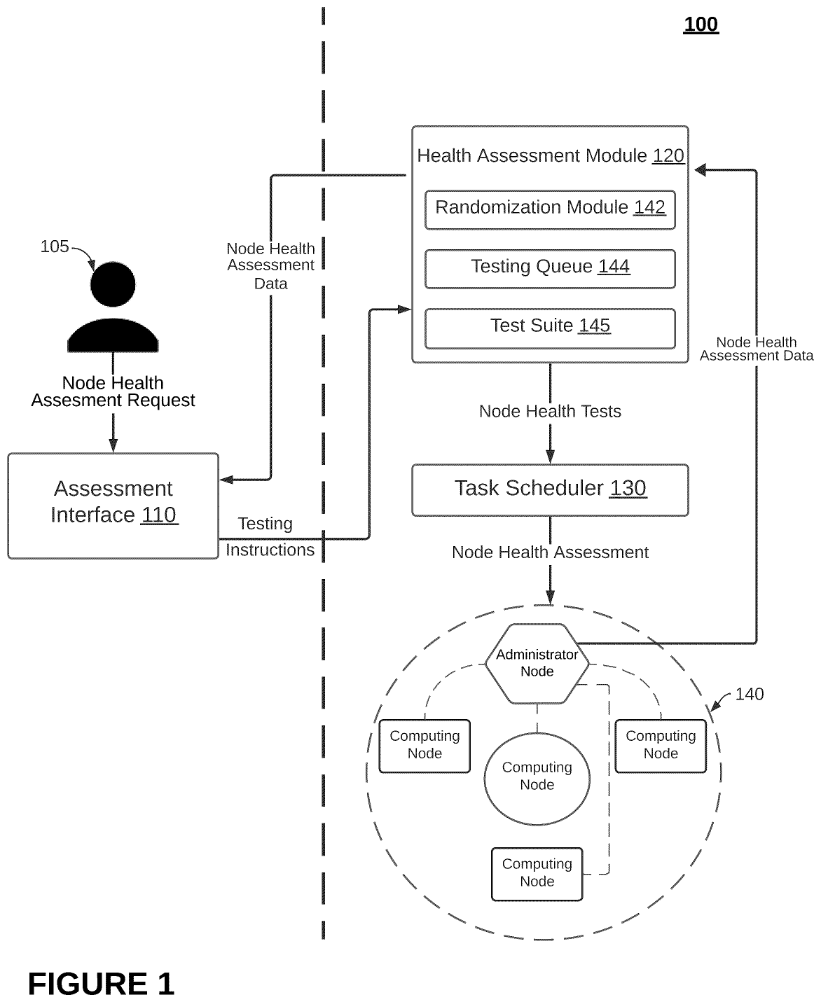

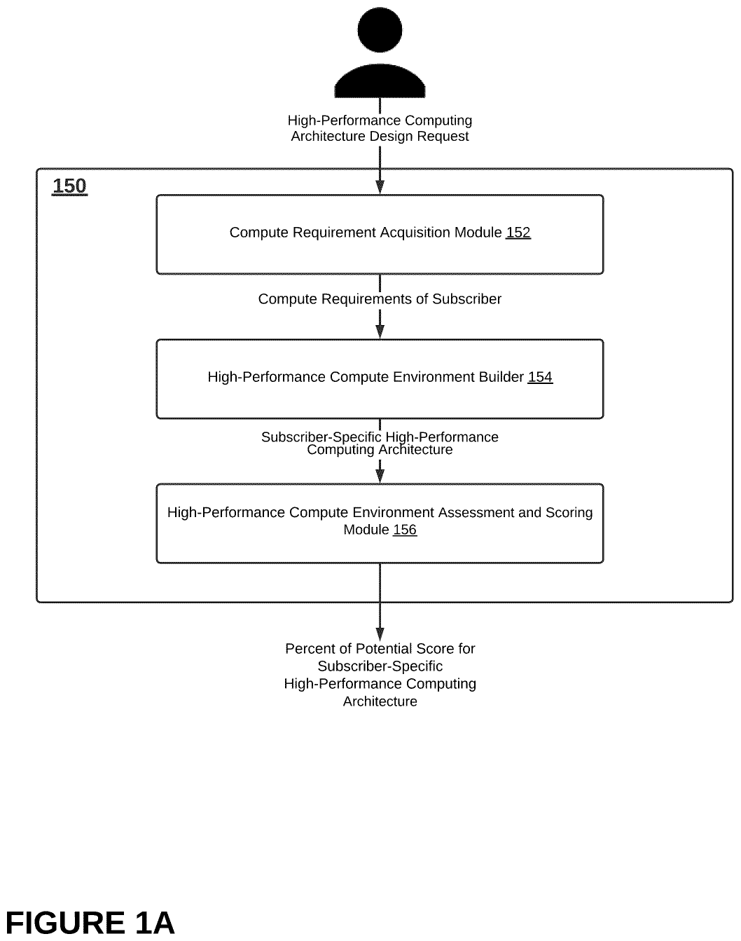

As shown in FIG. 1, a system 100 implementing enhanced cluster health management and for detecting unhealthy computing nodes within a cluster of computer nodes includes a node health assessment interface 110, a health assessment module 120, and a task scheduler 130 for assessing the health of a cluster of computing nodes 140.

### 1.1 Computing Node Health Assessment Interface

The node health assessment interface 110, which may also be referred to herein as assessment interface 110, preferably includes a command interface or system programming interface or console through which an administrator 105 may operate to execute a node health assessment of a target cluster of computing nodes 140. In a preferred embodiment, the assessment interface 110 is preferably implemented by one or more computers and may be in operable control communication with one or more computing nodes of a target cluster of computing systems. In such preferred embodiment, the assessment interface 110 may function to receive, as input, one or more user commands for executing one or more aspects of a node health assessment of a target cluster of computing nodes 140 and output control signals to the one or more computing nodes of the target cluster of computing nodes 140.

In one or more embodiments, the one or more computing nodes of a target cluster of computing nodes 140 that may be operably controlled via the assessment interface 110 preferably include an administrator node. In such embodiments, the administrator node comprises one computing node of the target cluster of computing nodes 140 that may be in network communication with all computing nodes of the target cluster of computing nodes 140. The administrator node executing commands or instructions from the assessment interface 110 may function to administer any suitable tests to the target cluster of computing nodes 140 including, but not limited to, a node health assessment. In some embodiments, the administrator node may be referred to herein as a head node or a control node depending on its operation within the cluster of computing nodes 140. Accordingly, the administrator node 105 may have installed cluster management software or similar applications that preferably enables the administrator node 105 to coordinate activities of the cluster of computing nodes 140, manage resource allocation, perform scheduling (e.g., integrated scheduler 130), and/or support maintaining an overall health of the cluster of computing nodes 140.

Additionally, or alternatively, the administrative node may be in operable control communication of a parallel file system or the like for administering any suitable tests, including a node health assessment, to a target cluster of computing nodes 140. Additionally, or alternatively, the administrative node may include an assessment agent installed thereon that may be in communication and operably controlled via commands from the assessment interface 110. In some embodiments, the assessment agent of the administrator node based on command inputs from the assessment interface 110 may function to automatically execute one or more operations or functions of a node health assessment against a target cluster of computing nodes 140.

### 1.2 Health Assessment Module

The health assessment module 120, in one or more embodiments, which is in operable communication with one or more of the assessment interface 110, the node assessment scheduler 130, and cluster of computing nodes 140 may operate to configure one or more node health assessments and/or execute one or more node health assessments against a target set of computing nodes of the cluster of computing nodes 140. In one or more embodiments, the health assessment module 120 may function to store and/or have access to a test suite 145, which is sometimes referred to herein as a pool of node health tests, that includes a plurality of node health tests. At runtime, the health assessment module 120 may function to source from the test suite 145 one or more node health tests, which may be executed either serially or in parallel against computing nodes of the cluster of computing nodes 140.

In one or more embodiments, the health assessment module 120 may be implemented in cooperation with a network file system, a parallel file system or the like. In such embodiments, the health assessment module 120 may be implemented by an administrative computing node of a target cluster of computing nodes, the administrative computing node may be sometimes referred to herein as a “head node” or “node zero”. Additionally, or alternatively, each computing node in the target cluster of computing nodes may store a copy of the tests and/or assessments associated with an operation of the health assessment module 120. In this way, commands and/or signals from the health assessment module 120 may cause any or each of the computing nodes of the target cluster to access one or more tests and/or assessments and execute the tests or assessments concurrently. In such embodiments, the outputs of the execution of the tests and/or assessments by the target cluster of computing nodes may be stored to or served out to the network file system.

Additionally, or alternatively, the health assessment module 120 may function to implement and/or include one or more of a randomization module 142 and a testing queue 144 that may operate together for initializing and executing a node health assessment of computing nodes of a cluster of computing nodes 140. In one or more embodiments, the randomization module 142 may function to ensure that different first computing nodes are seeded to prevent biased results on the basis of an initial computing node selection from a batch of computing nodes subject to a node health assessment.

### 1.3 Automated Task Scheduler

The task scheduler 130 preferably functions as an orchestration layer that automatically facilitates a node health assessment. In a preferred embodiment, the task scheduler 130 may function to integrate node health assessments directly into an operational workflow of the cluster of computing nodes 140. Accordingly, the task scheduler 130 may be multi-faceted in its automated application of node health assessments on a predetermined schedule or dynamically during a pre-job deployment of a batch of computing nodes.

In one or more embodiments, the task scheduler 130 may function to continually and/or periodically monitor a state of computing nodes within the cluster of computing nodes 140 to identify idle computing nodes that are not currently allocated to user jobs. In such embodiments, the task scheduler 130 may batch the idle computing nodes to the node testing queue 144 for a node health assessment.

### 1.4 Cluster of Computing Nodes

The cluster of computing nodes 140 preferably includes a plurality of distinct computing nodes where each distinct node comprises a computer. In a preferred embodiment, the computer typically includes a server-grade machine, equipped with one or more of central processing units (CPUs), graphical processing units (GPUs), both, or similar processing components capable of executing tasks and running applications. In one or more embodiments, the plurality of distinct computing nodes in a cluster may include network interconnects comprising high-speed communication pathways that link the computing nodes together, facilitating rapid data transfer. One or more examples of network interconnects may include, but should not be limited to, InfiniBand, Ethernet, fiber-optic connections that may enable the computing nodes to operate in concert for distributed computing tasks.

Additionally, or alternatively, a cluster of computing nodes may include a storage system having an associated memory or data storage solutions that may range from local disk drives within each computing node of the cluster of computing nodes 140 to shared storage systems, such as storage area network (SAN) or network attached storage (NAS), accessible by all computing nodes in cluster 140 for distributed file systems and data persistence. In a preferred embodiment, the cluster of computing nodes 140 preferably employs a parallel file system that allows multiple computing nodes to access and process data simultaneously, which may increase throughput and efficiencies of the computing nodes.

### 1.5 System for Generating and Scoring Subscriber-Specific Compute Architectures

As shown in FIG. 1A, a subsystem 150 (of the system 100) for generating and scoring subscriber-specific compute architectures may include a compute requirement acquisition module 152, a high-performance compute environment builder 154, and a high-performance compute environment assessment and scoring module 156. It shall be noted that subsystem 150 may operate independently of system 100 or in conjunction with system 100.

The compute requirement acquisition module 152, in one or more embodiments, may function to receive a high-performance computing architecture design request (e.g., AI compute architecture design request or the like) from a subscriber and output a set of compute requirements associated with the subscriber. The set of compute requirements may inform or control a design or generation of a high-performance computing architecture (e.g., AI compute architecture) requested by the subscriber. The set of compute requirements outputted by the compute requirement acquisition module 152, in some embodiments, may specify minimum performance thresholds likely needed for a target computing environment (e.g., high-performance computing environment, AI compute environment, etc.) to operate effectively under expected workloads and computational tasks of the subscriber.

The high-performance compute environment builder 154, in one or more embodiments, may function to receive, as input, the set of compute requirements associated with the subscriber (or a representation of the set of compute requirements) and output a subscriber-specific high-performance computing architecture (e.g., subscriber-specific AI compute architecture) based on the set of compute requirements. The subscriber-specific high-performance computing architecture may define the infrastructure or configuration of hardware components and software components likely needed to satisfy computational demands and use cases of the subscriber. The high-performance compute environment builder 154 may function to generate the subscriber-specific high-performance computing architecture by assessing the set of compute requirements associated with the subscriber and mapping each compute requirement of the set of compute requirements to one or more hardware components and/or one or more software components. It shall be recognized that “high-performance compute environment builder 154” may be interchangeably referred to herein as an “AI compute environment builder” or the like.

The high-performance compute environment assessment and scoring module 156, in one or more embodiments, may function to receive the subscriber-specific high-performance computing architecture (e.g., the subscriber-specific AI compute architecture or the like) and output a percent of potential score computed for the subscriber-specific high-performance computing architecture. The high-performance compute environment assessment and scoring module 156, in one or more embodiments, may function to compute the percent of potential score for the subscriber-specific high-performance computing architecture by evaluating the subscriber-specific high-performance computing architecture against a target reference compute architecture. Additionally, or alternatively, in one or more embodiments, the high-performance compute environment assessment and scoring module 156, in one or more embodiments, may function to compute the percent of potential score for the subscriber-specific high-performance computing architecture by evaluating the theoretical performance of the subscriber-specific high-performance computing architecture against the published performance of the target reference compute architecture. It shall be recognized that “high-performance compute environment assessment and scoring module 156” may be interchangeably referred to herein as an “AI compute environment assessment and scoring module” or the like.

Stated another way, in some embodiments, a compute architecture optimization service implemented by a distributed network of computers may function to obtain, via a graphical user interface, a set of compute architecture design parameters associated with a target subscriber. The set of compute architecture design parameters may include one or more distinct types of artificial intelligence (AI) compute tasks that the target subscriber intends to execute within a HPC environment, a set of compute architecture design constraints that may specify one or more immutable boundaries for controlling a compute architecture design space used by the compute architecture optimization service, and/or any other suitable set of compute architecture design parameters. The compute architecture design space may define or provide a range of permissible hardware and software configurations that satisfy the specified compute architecture design constraints, including, but not limited to, allowable compute node types, processor classes (e.g., CPUs, GPUs, AI accelerators, etc.), memory capacities and hierarchies, storage architectures (e.g., local SSD arrays, distributed storage fabrics, etc.), interconnect technologies (e.g., InfiniBand, Ethernet, NVLink, PCIe, etc.), switch and network topologies, power delivery budgets, cooling infrastructure types, firmware compatibility requirements, orchestration frameworks, and software stack parameters. In some embodiments, the compute architecture optimization service may use the compute architecture design space to guide and/or control the construction of a subscriber-specific compute architecture that satisfies both the compute performance objectives and the defined constraint boundaries of the target subscriber.

Accordingly, in one or more embodiments, the compute architecture optimization service may function to generate, by the distributed network of computers, a HPC architecture data object generated for the target subscriber that satisfies the set of compute architecture design parameters obtained via the graphical user interface. The HPC architecture data object, in some embodiments, may include a structured, machine-readable digital representation of a proposed subscriber-specific compute architecture, including an arrangement of hardware and software components that collectively define the architectural design of a candidate high-performance computing environment. In one or more embodiments, the compute architecture optimization service may function to generate the HPC architecture data object by translating the set of compute architecture design parameters into a respective set of hardware components and a respective set of software components that are collectively capable of supporting execution of the one or more distinct types of AI compute tasks and/or reside within the compute architecture design space formed according to the set of compute architecture design constraints.

Additionally, or alternatively, in one or more embodiments, in response to generating the HPC architecture data object generated for the target subscriber, the compute architecture optimization service may function to execute, in real-time or near-real-time by the distributed network of computers, one or more automated pairwise assessments (e.g., one automated pairwise assessment, ten automated pairwise assessments, thirty automated pairwise assessments, or any other suitable number of automated pairwise assessments) between the HPC architecture data object generated for the target subscriber and a reference HPC architecture data object. The reference HPC architecture data object, in some embodiments, may include a reference high-performance compute architecture provided by the compute architecture optimization service that exhibits optimal compute performance characteristics.

It shall be recognized that, in some embodiments, the compute architecture optimization service may include a plurality of distinct predetermined reference HPC architecture data objects. In such an embodiment, before executing the one or more automated pairwise assessments, the compute architecture optimization service may function to detect, via the graphical user interface, an input from a user selecting a target one of the plurality of distinct predetermined reference HPC architecture data objects. Accordingly, in such an embodiment, in response to detecting the input from the user selecting the target one of the plurality of distinct predetermined reference HPC architecture data objects, the compute architecture optimization service may function to automatically commence the one or more automated pairwise assessments.

It shall be further recognized that, in some embodiments, the compute architecture optimization service may automatically elect the reference HPC architecture data object to be assessed against the HPC architecture data object. Accordingly, in such an embodiment, in response to the compute architecture optimization service automatically electing the reference HPC architecture data object, the compute architecture optimization service may function to automatically commence the one or more automated pairwise assessments (e.g., one automated pairwise assessment, a plurality of distinct automated pairwise assessments, etc.).

Additionally, or alternatively, in one or more embodiments, in response to generating the HPC architecture data object generated for the target subscriber, the compute architecture optimization service may function to compute, in real-time or near real-time by the distributed network of computers, a percent of potential score that indicates a degree of performance disparity between the HPC architecture data object generated for the target subscriber and the reference HPC architecture data object based on pairwise assessment findings outputted by the one or more automated pairwise assessments.

Additionally, or alternatively, in one or more embodiments, in response to generating the HPC architecture data object generated for the target subscriber, the compute architecture optimization service may function to construct, in the real-world, an optimal HPC environment for the target subscriber that corresponds to the HPC architecture data object when the computed percent of potential score satisfies a predetermined minimum score threshold value. In other words, construction of the real-world high-performance computing environment may be commenced (e.g., only) after the compute architecture configuration defined by the HPC architecture data object is determined to meet or exceed the predetermined minimum score threshold value. Thereby ensuring that the real-world high-performance computing environment, once constructed, is optimally configured to achieve compute performance targets, reduce post-construction reconfiguration of the real-world high-performance computing environment, and maximize compute resource efficiency from initial operation.

### 2. Method for Designing and Scoring Subscriber-Specific Compute Architectures

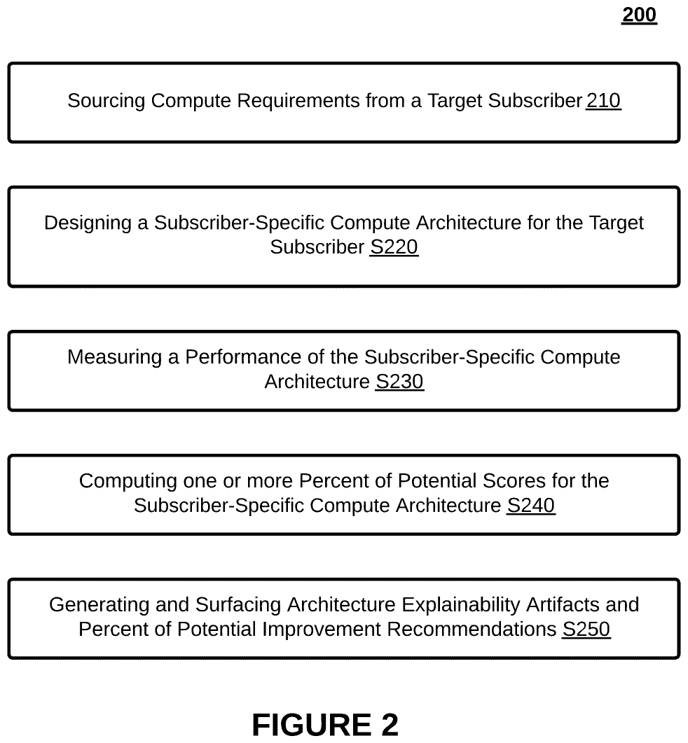

As shown in FIG. 2, a method 200 for designing and scoring subscriber-specific compute architectures may include sourcing compute requirements from a target subscriber S210, designing a subscriber-specific compute architecture for the target subscriber S220, measuring one or more performance attributes of the subscriber-specific compute architecture S230, computing one or more percent of potential scores for the subscriber-specific compute architecture S240, and generating and surfacing architecture explainability artifacts and percent of potential improvement recommendations S250.

As described in more detail herein, in some embodiments, a system or service—such as a compute architecture optimization service implemented by a distributed network of computers—may execute the method 200 to enable real-time generation and performance optimization of high-performance computing (HPC) architectures.

### 2.10 Sourcing Compute Requirements

S210, which includes sourcing compute requirements, may function to source, from a target subscriber, one or more compute requirements that may be used to design a high-performance computing architecture for the target subscriber. A high-performance computing architecture, as generally referred to herein, may include any suitable set or combination of hardware and software components that are operably configured to execute computationally intensive tasks. It shall be recognized that the phrase “high-performance computing architecture” may be interchangeably referred to herein as a “compute architecture”, “AI compute architecture,” “a HPC architecture data object,” or the like.

In one or more embodiments, S210 may function to receive a plurality of high-performance computing architecture design requests (e.g., AI compute architecture design requests, etc.) from a plurality of subscribers and, in turn, a system or service implementing method 200 may function to generate a corresponding subscriber-specific high-performance computing architecture (e.g., subscriber-specific AI compute architecture, respective HPC architecture data object, etc.) for each distinct request. For instance, in a non-limiting example, S210 may function to receive a high-performance computing architecture design request from a subscriber that relates to building a “new” high-performance computing environment and, in turn, the system or service implementing method 200 may function to generate or design a high-performance computing architecture that satisfies compute requirements of the “new” high-performance computing environment. In another non-limiting example, S210 may function to receive a high-performance computing architecture design request from a subscriber that relates to optimizing an existing high-performance computing environment and, in turn, the system or service implementing method 200 may function to generate or design a high-performance computing architecture that optimizes the existing high-performance computing environment of the subscriber. In another non-limiting example, S210 may function to receive an AI compute architecture design request from a subscriber and, in turn, the system or service implementing method 200 may function to generate or design an AI compute architecture based on the AI compute architecture design request.

It shall be recognized, in one or more embodiments, a subscriber may interface with at least a portion of a system or service implementing method 200 to specify or provide a set of compute requirements that may inform or control the design or configuration of the high-performance computing architecture (e.g., AI compute architecture, etc.) requested by the subscriber.

For instance, in one or more embodiments, S210 may function to source or collect, from a subscriber, a set of compute requirements that specifies one or more types of compute tasks that the subscriber intends to use compute resources of a high-performance computing environment (e.g., AI compute environment) to execute. Such compute requirements may serve as inputs into a system or service implementing method 200 to aid in designing a compute architecture that is capable of performing and/or executing each of the one or more types of compute tasks specified by the subscriber. For instance, in a non-limiting example, S210 may function to receive, from a subject subscriber, a set of compute requirements that indicates the subject subscriber intends to use the compute resources of the high-performance computing environment to train machine learning models (e.g., large language models (LLMs), convolutional neural networks (CNNs), recurrent neural networks (RNNs), etc.), conduct computer-based simulations, analyze datasets, perform computations, and/or perform any other suitable type of compute task without departing from the scope of the disclosure.

Additionally, or alternatively, in such embodiments, S210 may function to source or collect, from the subscriber, a set of compute requirements that specifies one or more workload requirements (e.g., computational demands, performance metrics) required for executing the above-mentioned compute tasks. Such workload requirements may serve as inputs into the system or service implementing method 200 to aid in designing the compute architecture in analogous ways as described above.

Additionally, or alternatively, in one or more embodiments, S210 may function to source or collect, from the subscriber, a set of compute resource constraints that may define immutable boundaries on the design or configuration of the high-performance computing architecture (e.g., AI compute architecture). Such compute resource constraints may include, but should not be limited to, budgetary constraints, overall compute cost constraints, hardware availability constraints, backend network infrastructure constraints, and/or any other suitable constraint or limitation. Such compute resource constraints may serve as inputs into the system or service implementing method 200 to aid in designing the compute architecture in analogous ways as described above.

Additionally, or alternatively, in one or more embodiments, S210 may function to source or collect, from the subscriber, existing and/or future compute resources of the subscriber, if any. For instance, in a non-limiting example, if S210 receives, from a target subscriber, a high-performance computing architecture design request related to optimizing an existing high-performance computing environment (e.g., existing AI compute environment, etc.), S210 may function to source or collect an existing set of compute resources (e.g., existing set of CPUs, existing set of GPUs, network bandwidth specifications, memory configurations, storage capacity, etc.) associated with the existing high-performance computing environment. In another non-limiting example, if S210 obtains a high-performance computing architecture design request related to building a “new” high-performance computing environment (e.g., new AI compute environment, etc.), S210 may function to source or collect, from a target subscriber, a future set of compute resources inbound to the subscriber (e.g., planned acquisitions of CPUs, GPUs, etc.).

In another non-limiting example, a compute architecture optimization service may function to obtain, via a graphical user interface or an application programming interface, a set of compute architecture design parameters associated with a target subscriber. The set of compute architecture design parameters, in such a non-limiting example, may include one or more distinct types of artificial intelligence (AI) compute tasks the target subscriber intends to execute within a HPC environment and/or a set of compute architecture design constraints specifying one or more immutable boundaries for controlling a compute architecture design space used by the compute architecture optimization service.

### 2.20 Designing a Subscriber-Specific Compute Architecture

S220, which includes designing a subscriber-specific compute architecture, may function to generate or design a distinct subscriber-specific compute architecture for each high-performance computing architecture design request obtained by S210. A subscriber-specific compute architecture, as generally referred to herein, may be a subscriber-specific configuration or layout of compute resources designed to satisfy computational demands and compute use cases of a particular subscriber. It shall be recognized that the phrase “subscriber-specific compute architecture” may be interchangeably referred to herein as a “subscriber-specific high-performance computing architecture,” “subscriber-specific AI compute architecture,” “a HPC architecture data object,” or the like.

In one or more embodiments, based on obtaining a set of compute requirements from a target subscriber, S220 may function to assess the compute requirements to determine a set of hardware components and/or software components likely needed to satisfy the set of compute requirements of the target subscriber. In such embodiments, assessing the compute requirements may include estimating minimum compute environment specifications (e.g., minimum bandwidth requirements, minimum latency requirements, minimum processing speed requirements, minimum resource utilization requirements, minimum number of compute nodes, etc.) based on the set of compute requirements. Stated another way, in one or more embodiments, the set of compute requirements obtained by S210 may be in an unstructured state and, in turn, S220 may function to translate the set of compute requirements of the target subscriber into a structured set of compute performance requirements that defines minimum compute performance thresholds likely necessary for a computing environment (e.g., high-performance computing environment, AI computing environment, etc.) to operate effectively under expected workloads of the target subscriber.

Additionally, or alternatively, in one or more embodiments, assessing the set of compute requirements of the target subscriber may include digitally mapping hardware components and/or software components to the compute requirements (e.g., computational tasks, AI use cases, workload requirements, etc.) of the target subscriber. In such embodiments, S220 may function to map one or more hardware components and/or one or more software components to each compute requirement of the set of compute requirements specified by the target subscriber.

For instance, in a non-limiting example, if one of the compute requirements of the set of compute requirements indicates using a computing environment (e.g., high-performance computing environment, AI compute environment, etc.) to train a large language machine learning model, S220 may function to digitally map a predetermined number of graphics processing units (GPUs) to the one of the compute requirements of the set of compute requirements. The graphics processing units (GPUS), in such embodiments, may be of a type capable of handling deep learning tasks efficiently, such as a Nvidia® H100 GPU.

Additionally, or alternatively, in such a non-limiting example, if one of the compute resource constraints of the set of compute resource constraints indicates using an ethernet-based backend, S220 may function to digitally map an ethernet-based backend networking infrastructure to the one of the compute resource constraints of the set of compute resource constraints. The ethernet-based backend networking infrastructure, in such embodiments, may be configured to facilitate data transmission between the predetermined number of graphics processing units.

It shall be recognized that, in one or more embodiments, S220 may function to map hardware components and/or software components to additional compute requirements, different compute requirements, or any other suitable type of compute requirement in analogous ways as described above.

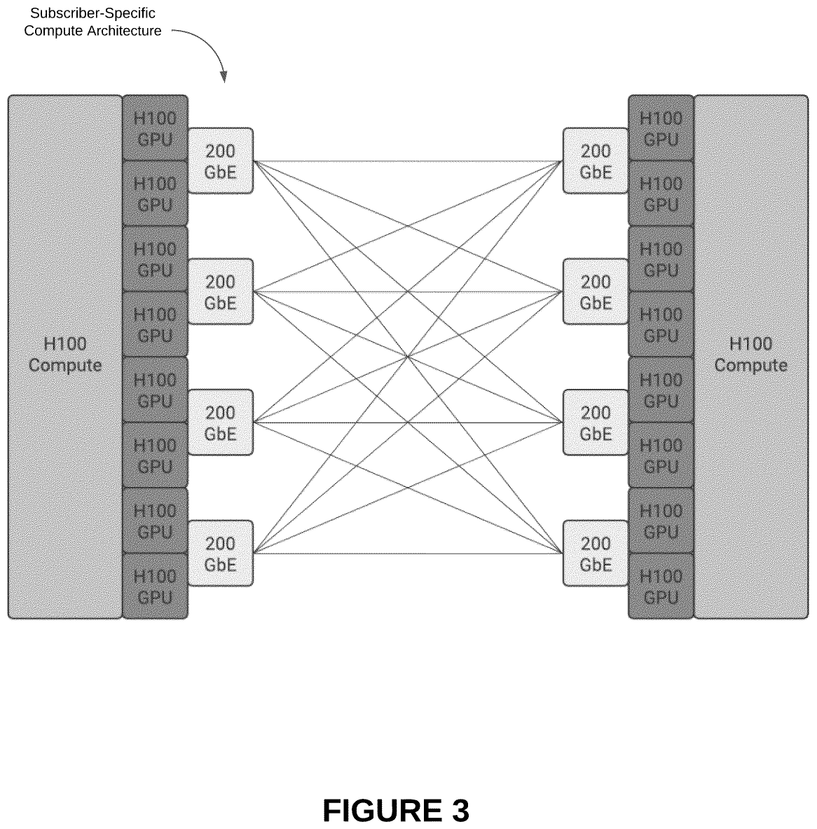

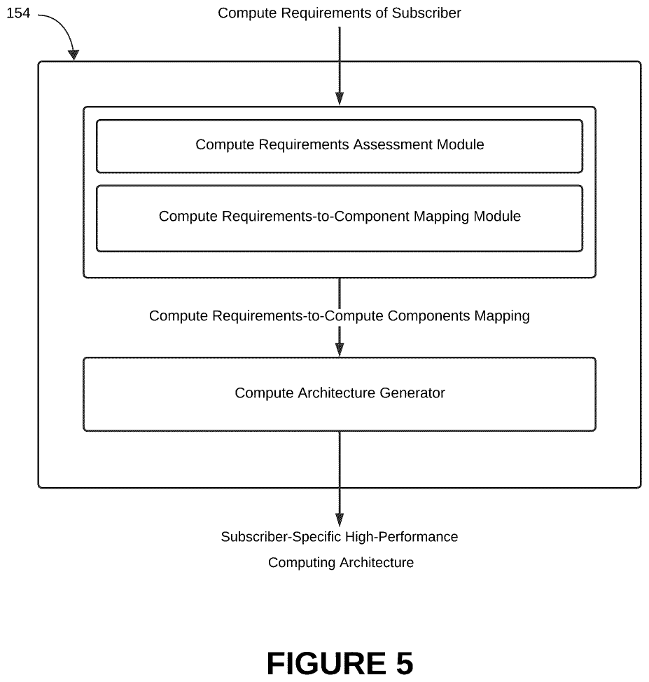

Accordingly, in one or more embodiments, S220 may function to generate a subscriber-specific compute architecture for a target subscriber based on assessing the compute requirements of the target subscriber and mapping prospective hardware components and/or prospective software components to the compute requirements of the target subscriber. For instance, in a non-limiting example, S220 may function to design or generate, for a target subscriber, a subscriber-specific compute architecture that may define the infrastructure or structure of a target compute environment (e.g., target high-performance computing environment, target AI compute environment, etc.) based on the compute requirements of the target subscriber, as shown generally by way of example in FIG. 3 and FIG. 5.

Stated another way, in one or more embodiments, in response to obtaining a set of compute architecture design parameters associated with a target subscriber, S220 may function to generate, by a distributed network of computers, a HPC architecture data object for the target subscriber that satisfies the set of compute architecture design parameters associated with the target subscriber. In such an embodiment, generating the HPC architecture data object for the target subscriber may include one or more of translating the set of compute architecture design parameters into a set of hardware components and a set of software components that are collectively capable of supporting execution of one or more distinct types of AI compute tasks specified by the target subscriber and/or reside within a compute architecture design space formed according to the set of compute architecture design parameters, instantiating, by the distributed network of computers, a data model based on a predetermined compute architecture schema provided by the compute architecture optimization service in response to translating the set of compute architecture design parameters into the set of hardware components and the set of software components, and encoding, by the distributed network of computers, the data model to include the set of hardware components and the set of software components.

In other words, the HPC architecture data object generated for the target subscriber may serve as a structured digital representation of a proposed compute architecture that may be encoded with all necessary hardware and software components required to support the execution of AI compute tasks in accordance with the subscriber-provided design parameters and constraints. The structured digital representation of the proposed compute architecture may enable the compute architecture optimization service to programmatically assess, compare, and iteratively refine the proposed compute architecture prior to any physical deployment or construction of a HPC environment corresponding to the proposed compute architecture, thereby reducing compute architecture configuration errors, and accelerating time-to-deployment for high-performance computing environments.

### 2.30 Measuring Performance of Subscriber-Specific Compute Architectures and Reference Compute Architectures

S230, which includes measuring a performance of a target subscriber-specific compute architecture and a target reference compute architecture, may function to measure the target subscriber-specific compute architecture and the target reference compute architecture against one or more predetermined performance efficacy metrics. A reference compute architecture, as generally referred to herein, may be an optimal compute configuration or optimal system configuration that enables compute hardware to operate at peak capacity without any performance bottlenecks. In other words, the compute resources (e.g., hardware-type compute resources (e.g., hardware components), software-type compute resources (e.g., software components), etc.) of a reference compute architecture may be operably configured in such a way to obtain maximum compute performance with little-to-no bottlenecks (e.g., hardware bottlenecks, software bottlenecks, etc.).

It shall be recognized that, in one or more embodiments, a system or service implementing method 200 may have the capability to access a plurality of predetermined reference compute architectures. In such embodiments, each distinct reference compute architecture of the plurality of predetermined reference compute architectures may be specifically designed or optimized for a particular type of computational task. For instance, in a non-limiting example, one of the plurality of predetermined reference compute architectures may be optimized for executing computer-based simulations. Additionally, or alternatively, in such a non-limiting example, another one of the plurality of predetermined reference compute architectures may be optimized for performing deep learning tasks (e.g., model training, etc.). Additionally, or alternatively, in such a non-limiting example, another one of the plurality of predetermined reference compute architectures may be optimized for large-scale data analytics. In this way, a system or service implementing method 200 may intelligently and/or automatically select a reference compute architecture from the plurality of predetermined reference compute architectures for downstream assessment and evaluation against a target subscriber-specific compute architecture, rather than defaulting to a fixed or static reference compute architecture.

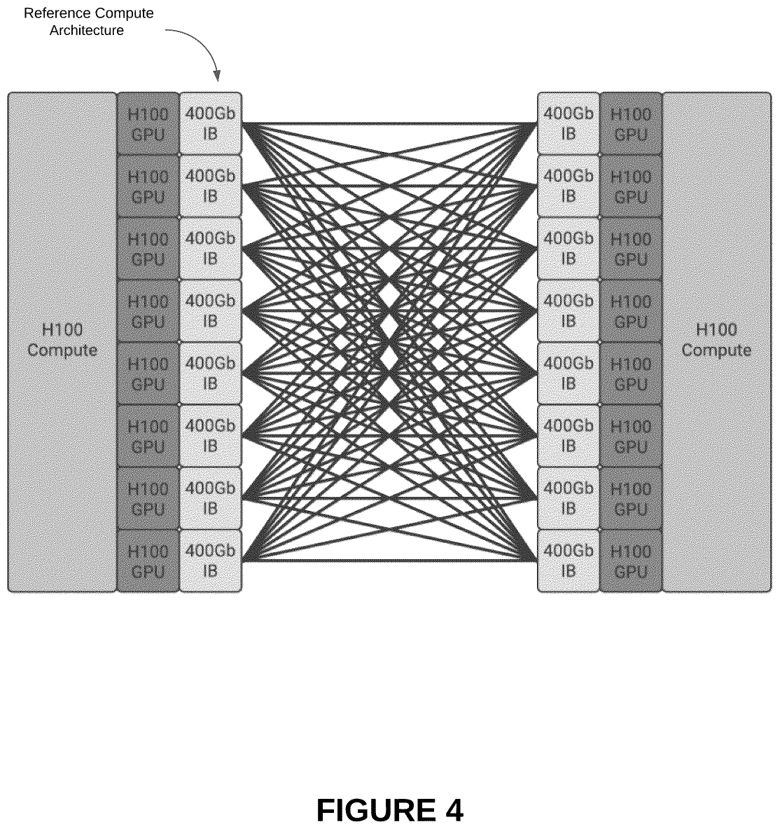

It shall be further recognized that, in some embodiments, the target reference compute architecture may be a fixed, static, or standardized reference compute architecture without departing from the full scope of the disclosure. FIG. 4 illustrates a non-limiting example of a reference compute architecture. It shall be recognized that the reference compute architecture illustrated in FIG. 4 may be fully interconnected by a low-latency, high-bandwidth non-blocking network that allows the GPUs to run at maximum performance or capacity (e.g., full speed).

It shall be further recognized that FIG. 4 illustrates an example embodiment of a reference compute architecture having two (2) computing nodes. Those skilled in the art can appreciate that this configuration of the reference compute architecture may include any suitable number of computing nodes. For instance, in a non-limiting example, the reference compute architecture may include two (2) or more computing nodes, three (3) or more computing nodes, four (4) or more computing nodes, five (5) or more computing nodes, six (6) or more computing nodes, seven (7) or more computing nodes, eight (8) or more computing nodes, nine (9) or more computing nodes, ten (10) or more computing nodes, eleven (11) or more computing nodes, twelve (12) or more computing nodes, thirteen (13) or more computing nodes, fourteen (14) or more computing nodes, fifteen (15) or more computing nodes, sixteen (16) or more computing nodes, seventeen (17) or more computing nodes, eighteen (18) or more computing nodes, nineteen (19) or more computing nodes, twenty (20) or more computing nodes, twenty-one (21) or more computing nodes, twenty-two (22) or more computing nodes, twenty-three (23) or more computing nodes, twenty-four (24) or more computing nodes, twenty-five (25) or more computing nodes, twenty-six (26) or more computing nodes, twenty-seven (27) or more computing nodes, twenty-eight (28) or more computing nodes, twenty-nine (29) or more computing nodes, thirty (30) or more computing nodes, thirty-one (31) or more computing nodes, thirty-two (32) or more computing nodes, or any other suitable number of computing nodes.

### Extrapolating Theoretical Performance of Subscriber-Specific Compute Architecture

In one or more embodiments, based on generating or designing a subscriber-specific compute architecture for a target subscriber, S230 may function to measure the performance of the subscriber-specific compute architecture using performance characteristics of the target reference compute architecture as a baseline. In such embodiments, S230 may function to compute one or more performance efficacy metrics of the subscriber-specific compute architecture by evaluating the subscriber-specific compute architecture against the target reference compute architecture. It shall be recognized, in such embodiments, the target reference compute architecture may be associated with a set of published performance efficacy metrics or performance attributes previously validated or confirmed by the system or service implementing method 200 (e.g., the target reference compute architecture has a maximum bandwidth capacity of 3.2 terabits per second, etc.).

In such embodiments, based on identifying compute architecture differences between the subscriber-specific compute architecture designed for the target subscriber and the target reference compute architecture, S230 may function to extrapolate theoretical performance attributes of the subscriber-specific compute architecture. For instance, in a non-limiting example, the subscriber-specific compute architecture and the target reference compute architecture may only differ in their backend networking infrastructure (e.g., the subscriber-specific compute architecture may have an ethernet-based backend networking infrastructure, whereas the target reference compute architecture may have an InfiniBand-based backend networking infrastructure). Accordingly, in such embodiments, S230 may function to query, search or lookup within a performance degradation repository or any other suitable data structure a performance degradation factor associated with the compute architecture difference or deviation.

For instance, with reference to the above non-limiting example, S230 may function to identify that an ethernet-based backend networking infrastructure is associated with a performance degradation factor of fifteen (15) percent based on searching the performance degradation repository. Accordingly, in such a non-limiting example, S230 may function to compute or extrapolate that the theoretical performance of the subscriber-specific compute architecture is fifteen percent less than the target reference compute architecture (e.g., if the target reference compute architecture has a maximum bandwidth capacity of 3.2 terabits per second, S230 may determine that the theoretical maximum bandwidth capacity of the subscriber-specific compute architecture is 2.72 terabits per second, etc.).

It shall be noted that, in one or more embodiments, S230 may function to compute performance characteristics of the subscriber-specific compute architecture for other types of compute architecture differences in analogous ways as described above.

It shall be further noted that, in one or more embodiments, S230 may function to compute additional or different types of theoretical performance characteristics or metrics of the subscriber-specific compute architecture, including but not limited to, theoretical latency, theoretical processing speed, theoretical energy consumption rate, and theoretical throughput without departing from the full scope of the disclosure.

It shall be further recognized that, in some embodiments, S230 may use one or machine learning models to predict performance characteristics of the subscriber-specific compute architecture based on providing detected compute architecture deviations of the subscriber-specific compute architecture as model input to the one or machine learning models. In such embodiments, the one or more machine learning models may be trained on a (e.g., labeled) historical corpus of compute architecture configurations and corresponding compute performance metrics, enabling the one or more machine learning models to accurately predict one or more theoretical performance characteristics of the subscriber-specific compute architecture, such as the theoretical maximum bandwidth capacity of the subscriber-specific compute architecture. It shall be further recognized that using the one or more machine learning models in this manner may allow S230 to improve the fidelity and contextual accuracy of theoretical performance extrapolations, particularly in complex scenarios where rule-based degradation factors may not fully capture system-wide performance interactions.

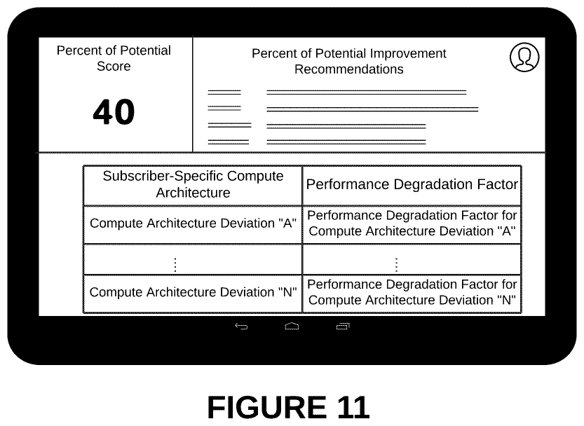

Additionally, or alternatively, in one or more embodiments, the compute architecture optimization service may function to detect, during the execution of one or more automated pairwise assessments, a plurality of compute architecture deviations between a target HPC architecture data object generated for a target subscriber and a target reference HPC architecture data object. In one or more embodiments, the compute architecture optimization service may function to attribute a corresponding performance degradation factor to each compute architecture deviation of the plurality of compute architecture deviations. Accordingly, in one or more embodiments, the compute architecture optimization service may function to display, via a graphical user interface, a data table that includes the plurality of compute architecture deviations in association with their respective corresponding performance degradation factor, as shown generally by way of example in FIG. 11.

### Real-World Measuring of Subscriber-Specific Compute Architecture

In one or more embodiments, S230 may function to perform one or more performance tests on a real-world compute environment that was constructed based on the subscriber-specific compute architecture designed for the target subscriber.

For instance, in a first implementation, S230 may function to perform a NVIDIA® Collective Communications Library (NCCL) all-reduce test on the real-world compute environment. Accordingly, in such implementation, in response to executing the NCCL all-reduce test on the real-world compute environment, the NCCL all-reduce test may output a throughput performance metric that indicates the amount of data that can be processed per second, a latency performance metric that indicates the amount of time for the all-reduce operation to complete, and/or one or more scaling performance metrics that indicate the communication efficiency and computational workload distribution across multiple GPUs or nodes of the real-world compute environment.

It shall be recognized that, in one or more embodiments, S230 may function to execute any suitable standardized test that measures the performance of the real-world compute environment.

### 2.40 Computing Percent of Potential Scores

S240, which includes computing percent of potential scores, may function to compute a percent of potential score for each subscriber-specific compute architecture designed or generated by the system or service implementing method 200. A percent of potential (POP) score, as generally referred to herein, may be a quantitative measure that indicates a degree of performance disparity between a target subscriber-specific compute architecture (e.g., HPC architecture data object) generated for a target subscriber and a target reference compute architecture (e.g., reference HPC architecture data object, etc.). It shall be recognized that the percent of potential score computed for a subject subscriber-specific compute architecture (e.g., HPC architecture data object) may fall between any two values (e.g., 0-100), a set of alphanumeric characters (e.g., A-Z), or any range of non-numerical indicators (e.g., color gradations like green to yellow to red, or descriptive levels like low to intermediate to high, etc.).

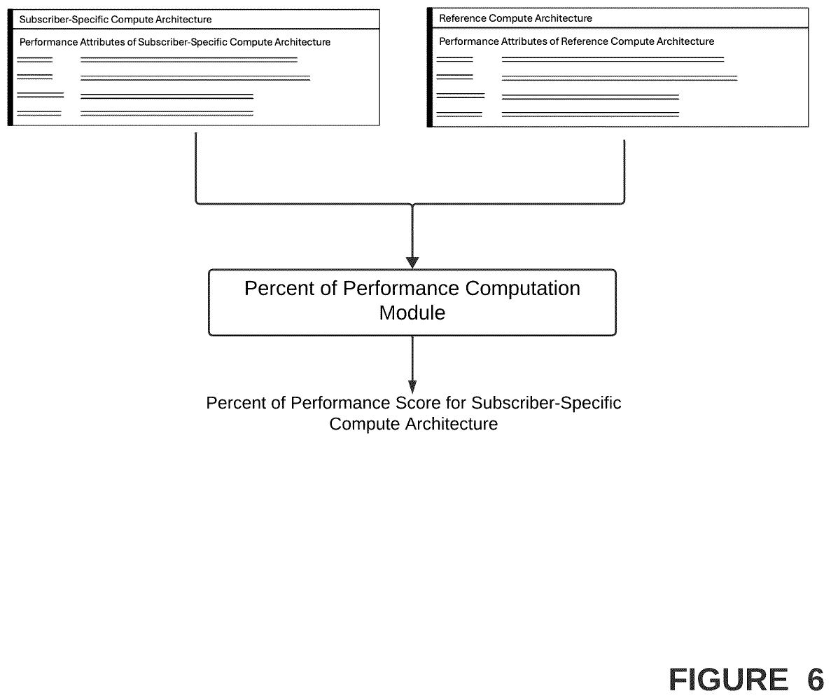

In a first implementation, S240 may function to compute a percent of potential score for a subject subscriber-specific compute architecture based on performing a pairwise performance assessment between the subject subscriber-specific compute architecture and a target reference compute architecture. In such embodiments, S240 may function to obtain the theoretical performance attributes of the subject subscriber-specific compute architecture and the published performance attributes of the target reference compute architecture and, in turn, compute the percent of potential score for the subject subscriber-specific compute architecture based on a performance disparity between the subject subscriber-specific compute architecture and the target reference compute architecture. For instance, in a non-limiting example, if S240 determines the subject subscriber-specific compute architecture achieved eighteen (18) percent of the performance of the target reference compute architecture, S240 may function to assign the percent of potential score of eighteen (18) to the subject subscriber-specific compute architecture, as shown generally by way of FIG. 6.

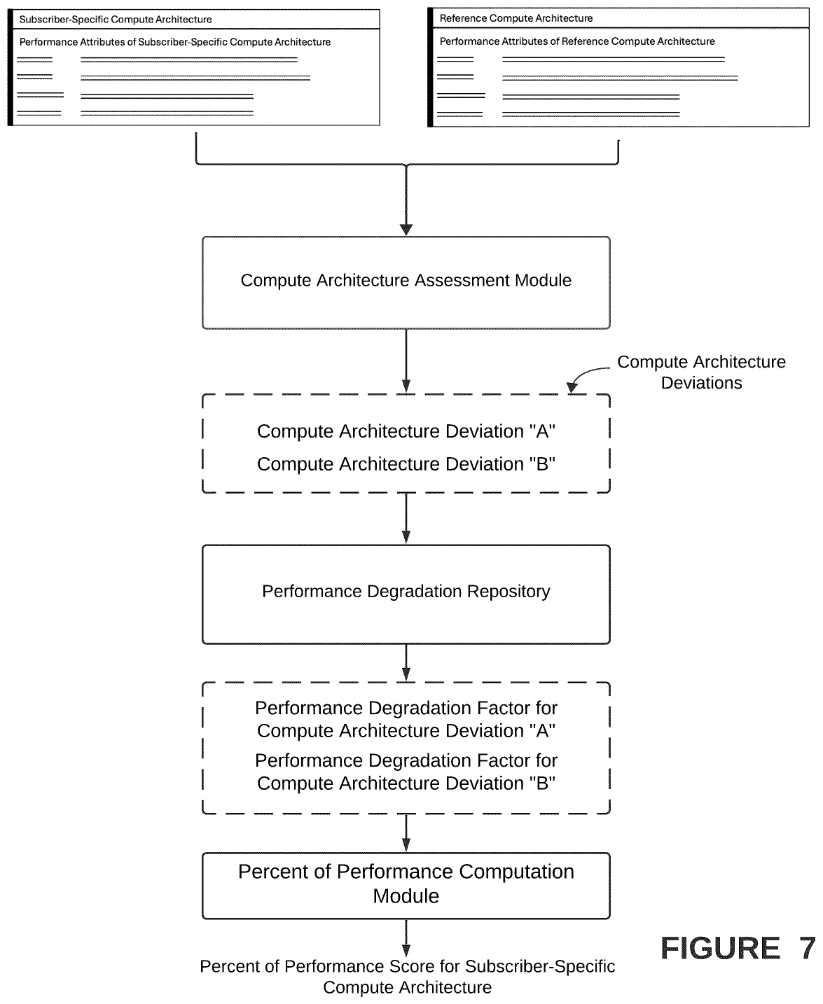

In a second implementation, S240 may function to compute a percent of potential score for a subject subscriber-specific compute architecture based on performing a pairwise assessment between the subject subscriber-specific compute architecture and a target reference compute architecture. In such embodiments, S240 may function to identify where the subject subscriber-specific compute architecture deviates or differs from the target reference compute architecture and, in turn, identify a corresponding performance degradation factor for each identified deviation or difference. For instance, in a non-limiting example, S240 may function to identify a backend networking infrastructure deviation between the subject subscriber-specific compute architecture and the target reference compute architecture (e.g., the subject subscriber-specific compute architecture may have an ethernet-based backend networking infrastructure, whereas the target reference compute architecture may have an InfiniBand-based backend networking infrastructure) and, in turn, the backend networking infrastructure deviation may be assigned a performance degradation factor of fifteen (15). In another non-limiting example, S240 may function to identify a GPU type deviation between the subject subscriber-specific compute architecture and the target reference compute architecture (e.g., the subject subscriber-specific compute architecture may be designed with Nvidia® Tesla Pioos, whereas the target reference compute architecture may be designed with Nvidia® A100 GPUS) and, in turn, the GPU type deviation may be assigned a performance degradation factor of thirty (30). Accordingly, since the target reference compute architecture has a system-default percent of potential score of one hundred (100), S240 may function to calculate the percent of potential score of the subscriber-specific compute architecture by deducting, from the percent of potential score of the target reference compute architecture, each performance degradation factor attributed to the identified deviations. Thus, in such a non-limiting example, the percent of potential score of the subscriber-specific compute architecture may be fifty-five (55) (e.g., 100 minus 30 minus 15=55), as shown generally by way of example in FIG. 7.

In a third implementation, S240 may function to compute a percent of potential score for a subject subscriber-specific compute architecture based on performing a pairwise assessment between a subject subscriber-specific compute environment that was constructed based on the subject subscriber-specific compute architecture and a target reference compute architecture. In one or more embodiments of such an implementation, the subject subscriber-specific compute architecture and the target reference compute architecture may be identical as the subscriber may have chosen or selected to implement the target reference compute architecture. Accordingly, in such embodiments, S240 may function to compute a percent of potential score for the subject subscriber-specific compute environment by evaluating real-world performance of the subject subscriber-specific compute environment against the expected (or published) performance metrics of the target reference compute architecture. The computed percent of potential score may indicate a performance disparity between the subject subscriber-specific compute environment and the target reference compute architecture, if any.

For instance, in a non-limiting example, the percent of potential score computed for the subject subscriber-specific compute environment may be seventy (70), indicating that the subject subscriber-specific compute environment is only achieving seventy (70) percent of the potential performance as defined by the target reference compute architecture. The percent of potential score, in such a non-limiting example, may indicate that the subject subscriber-specific compute environment is experiencing a performance shortfall of thirty (30) percent, which may be attributed to real-world deployment or implementation errors (e.g., misapplication of software settings, miswirings in the network, or other deployment inefficiencies). In other words, the performance disparity may be caused by deployment (or implementation) errors rather than architectural design choices. It shall be recognized that for computing percent of potential scores for subscriber-specific compute environments, reference is made to U.S. Patent Application No. 63/782,317, filed on 2 Apr. 2025, titled SYSTEMS AND METHODS FOR ASSESSING AND SCORING HIGH-PERFORMANCE COMPUTE ARCHITECTURES, which is incorporated herein in its entirety by this reference.

In a fourth implementation, S240 may function to compute one or more percent of potential scores (e.g., one percent of potential score, two or more percent of potential scores, three or more percent of potential scores, four or more percent of potential scores, five or more percent of potential scores, etc.) for a subject subscriber-specific compute architecture. In such embodiments, a system or service implementing method 200 may function to provide a plurality of predetermined selectable normalization factors to a user of the system or service. The plurality of predetermined selectable normalization factors may include, but should not be limited to, a bandwidth normalization factor, a processing speed normalization factor, a latency normalization factor, a standardized test normalization factor, and a resource utilization normalization factor. It shall be noted that each distinct normalization factor of the plurality predetermined selectable normalization factors may serve as a benchmark or criterion against which the performance of the subject subscriber-specific compute architecture is evaluated.

Accordingly, in one or more embodiments, based on receiving, from the user, a selection of one or more normalization factors, S240 may function to compute a distinct percent of potential score for each selected normalization factor. For example, if the user selects the bandwidth normalization factor and the latency normalization factor, S240 may function to compute a first distinct percent of potential score for the subject subscriber-specific compute architecture based on bandwidth and a second distinct percent of potential score for the subject subscriber-specific compute architecture based on latency.

Stated another way, in one or more embodiments, if the user selects the bandwidth normalization factor, S240 may function to compute a percent of potential score for the subject subscriber-specific compute architecture based on receiving the selection. For instance, in a non-limiting example, if the subject subscriber-specific compute architecture has a maximum bandwidth capacity of seventy (70) gigabits per second and a target reference compute architecture has a maximum bandwidth capacity of one hundred and ninety-two gigabits per second, the percent of potential score for the subject subscriber-specific compute architecture may be 36.5

$$( e . g . , \frac{70 gigabits per second}{192 gigabits per second} = 36.5 ) .$$

It shall be recognized that, in some embodiments, the percent of potential score for the subject subscriber-specific compute architecture may be computed by dividing the product of (i) the bandwidth of the subscriber-specific compute architecture, (ii) the number of compute nodes included in the subscriber-specific compute architecture, and (iii) the amount of time the subscriber-specific compute architecture or associated compute environment is expected to be operational, by the product of (i) the bandwidth of the reference compute architecture, (ii) the number of compute nodes included in the reference architecture, and (iii) the amount of time the reference compute architecture or associated reference compute environment is expected to be operational (e.g., total seconds in a year). In other words, a POP score normalized for bandwidth may be computed using the expression PoP=(Bandwidth x Number of Compute Nodes x Time) (Reference Bandwidth x Number of Compute Nodes x Max Time).

Additionally, or alternatively, in embodiments in which multiple percent of potential scores are computed for a subject subscriber-specific compute architecture, S240 may function to compute a composite percent of potential score based on the multiple percent of potential scores computed for the subject subscriber-specific compute architecture. In one or more embodiments, the composite percent of potential score computed for subject subscriber-specific compute architecture may be an averaged percent of potential score (e.g., summing the multiple percent of potential scores and dividing the sum of percent of potential scores by the total number of the percent of potential score computed). In one or more alternative embodiments, the composite percent of potential score computed for subject subscriber-specific compute architecture may be a weighted average (e.g., multiplying each distinct percent of potential score by its respective weight and dividing the total by the sum of the weights (e.g., each distinct percent of potential score of the multiple percent of potential scores may be assigned a specific weight based on its relevance or impact).

Additionally, or optionally, in some embodiments, S240 may function to adapt or tune the computed percent of potential score for a subject subscriber-specific compute architecture based on a non-idealities factor. In this way, the adapted or tuned percent of potential score may account for software inefficiencies and/or any other non-idealities that may affect performance.

Additionally, or alternatively, in another non-limiting example, in response to generating the HPC architecture data object for the target subscriber, the compute architecture optimization service may function to execute, in real-time or near real-time, one or more automated pairwise assessments between the HPC architecture data object generated for the target subscriber and a reference HPC architecture data object and, in turn, compute, in real-time or near real-time by the distributed network of computers, a percent of potential score that indicates a degree of performance disparity between the HPC architecture data object generated for the target subscriber and the reference HPC architecture data object based on pairwise assessment findings outputted by the one or more automated pairwise assessments.

For instance, in one embodiment, at least one of the one or more automated pairwise assessments may detect that a first compute architecture deviation exists between the HPC architecture data object generated for the target subscriber and the reference HPC architecture data object and, in turn, the compute architecture optimization service may function to automatically retrieve, using a distributed network of computers, a performance degradation factor that corresponds to the first compute architecture deviation in response to querying a performance degradation repository using the first compute architecture deviation as a query parameter. Accordingly, the percent of potential score may be computed by deducting the performance degradation factor that corresponds to the first compute architecture deviation from a service-default percent of potential score attributed to the reference HPC architecture data object.

In another embodiment, the one or more automated pairwise assessments may have detected that a plurality of compute architecture deviations exist between the HPC architecture data object generated for the target subscriber and the reference HPC architecture data object and, in turn, the compute architecture optimization service may function to automatically retrieve, using the distributed network of computers, a respective performance degradation factor that corresponds to each compute architecture deviation of the plurality of compute architecture deviations in response to querying a performance degradation repository using the plurality of compute architecture deviations as query parameters. Accordingly, the percent of potential score may have been computed for the HPC architecture data object by deducting the respective performance degradation factor that corresponds to each compute architecture deviation of the plurality of compute architecture deviations from a service-default percent of potential score attributed to the reference HPC architecture data object.

It shall be recognized that, in one or more embodiments, the one or more automated pairwise assessments may function to assess the HPC architecture data object generated for the target subscriber and the reference HPC architecture data object across multiple distinct compute dimensions (e.g., processor type, number of compute cores, clock frequency, memory capacity, memory bandwidth, cache structure, node interconnect topology, storage throughput, I/O latency, and inclusion of hardware accelerators such as GPUs or FPGAs). For instance, in a non-limiting example, executing the one or more automated pairwise assessments may include one or more of assessing a maximum bandwidth capacity of the HPC architecture data object against the maximum bandwidth capacity of the reference HPC architecture data object, assessing a total number of computing nodes included in the HPC architecture data object against the total number of computing nodes included in the reference HPC architecture data object, assessing a backend networking infrastructure of the HPC architecture data object against the backend networking infrastructure of the reference HPC architecture data object, assessing a type of graphics processing units included in the HPC architecture data object against the type of graphics processing units included in the reference HPC architecture data object, and assessing a network latency profile of the HPC architecture data object against a network latency profile of the reference HPC architecture data object.

It shall be further recognized that, in one or more embodiments, an optimal HPC environment that corresponds to a respective HPC architecture data object may be constructed for the target subscriber based on detecting or determining the percent of potential score computed for the respective HPC architecture data object satisfies the predetermined minimum score threshold value. In such an embodiment, constructing the optimal HPC environment for the target subscriber may include at least physically installing a plurality of computing nodes specified by the respective HPC architecture data object at a target real-world location or a target physical location, wherein each computing node of the plurality of computing nodes includes a plurality of graphics processing units (GPUs) and a plurality of central processing units (CPUs) and physically connecting the plurality of computing nodes together using a plurality of physical networking components as specified by the respective HPC architecture data object. In other words, the respective HPC architecture data object may include a digital representation of the physical arrangement and interconnection topology of the HPC environment-including the placement and interconnection of compute nodes—in sufficient detail to enable implementation of hardware-level infrastructure, such as wiring, cabling, switch placement, and port-level routing, such that the resulting physical deployment conforms to the validated compute and communication design specified by the respective HPC architecture data object.

### Iterative Adaptation of HPC Architecture Data Object

In one or more embodiments, the percent of potential score computed for a HPC architecture data object generated for a target subscriber may not satisfy a predetermined minimum score threshold value (e.g., the percent of potential score must exceed a minimum score threshold value of eighty, etc.). In one or more embodiments, in response to detecting the percent of potential score computed for the HPC architecture data object does not satisfy the predetermined minimum score threshold value, the system or service implementing method 200 (e.g., compute architecture optimization service or the like) may function to automatically route or provide the HPC architecture data object generated for the target subscriber and the corresponding reference HPC architecture data object as input (e.g., model input) to a machine learning model, and in turn, the machine learning model may function to predict, using the machine learning model, one or more percent of potential improvement recommendations for the HPC architecture data object based on the machine learning model assessing the HPC architecture data object generated for the target subscriber and the corresponding reference HPC architecture data object.

It shall be recognized that, in such an embodiment, the system or service implementing method 200 may have trained the machine learning model by training a target machine learning model (e.g., large language model, transformer-based model, or any other suitable machine learning model) using a corpus of training data comprising a plurality of labeled sequences of compute architecture improvement operations. In some embodiments, each training sequence of the plurality of labeled sequences of compute architecture improvement operations may include: (i) an initial subscriber-specific HPC architecture data object having a percent of potential score below a predetermined minimum threshold, (ii) a corresponding reference HPC architecture data object, (iii) a series of compute architecture modifications applied to the initial subscriber-specific HPC architecture data object over one or more iterations, and (iv) a final revised subscriber-specific HPC architecture data object having a percent of potential score that satisfies the predetermined minimum threshold. By training on such sequences, the target machine learning model may learn to predict compute architecture-level changes that are likely to improve the percent of potential score. In this way, the machine learning model may enable automated generation of targeted compute architecture design recommendations that guide the iterative refinement of subscriber-specific compute architectures.

Additionally, or alternatively, in one or more embodiments, S240 may function to adapt (e.g., automatically adapt, semi-automatically adapt, etc.) the HPC architecture data object generated for the target subscriber to an adapted HPC architecture data object based on the one or more percent of potential improvement recommendations predicted by the machine learning model and, in turn, S240 may function to automatically compute, in real-time or near real-time by the distributed network of computers, a second percent of potential score for the adapted HPC architecture data object indicating a degree of performance disparity between the adapted HPC architecture data object and the reference HPC architecture data object, wherein the second percent of potential score computed for the adapted HPC architecture data object satisfies the predetermined minimum score threshold value. Accordingly, based on or in response to detecting the second percent of potential score satisfying the predetermined minimum score threshold value, an optimal HPC environment for the target subscriber may be constructed in the real-world (e.g., physical world) that corresponds to the adapted HPC architecture data object.

It shall be recognized that, in some embodiments, the one or more percent of potential improvement recommendations may include one or more of a first percent of potential improvement recommendation that textually indicates replacing an ethernet-based networking configuration (e.g., 200 Gigabit Ethernet (GbE)) specified by the HPC architecture data object with an InfiniBand-based networking configuration, a second percent of potential improvement recommendation that textually indicates updating a firmware version associated with one or more hardware components specified by the HPC architecture data object to a current firmware version or at least more recent firmware version than the firmware version currently specified by the HPC architecture data object, a third percent of potential improvement recommendation that textually indicates increasing a total number of compute nodes specified by the HPC architecture data object to a greater quantity of compute nodes than currently specified by the HPC architecture data object, and a fourth percent of potential improvement recommendation that textually indicates replacing a first type of graphics processing unit (GPU) specified by the HPC architecture data object with a different GPU type.

It shall be further recognized, in some embodiments, a percent of potential value (e.g., percent of potential score) computed for a subscriber-specific compute architecture (e.g., HPC architecture data object generated for a target subscriber) may further be based on any system bottleneck detected in the subscriber-specific compute architecture or the HPC environment corresponding to the subscriber-specific compute architecture. Such detected system bottlenecks may include, but are not limited to, compute-type bottlenecks (e.g., insufficient graphics processing units (GPUs) or central processing units (CPUs), suboptimal processing units, etc.), memory-type bottlenecks (e.g., memory bandwidth being below a predetermined minimum memory bandwidth threshold, memory latency exceeding a predetermined memory latency threshold, limited memory capacity, etc.), storage-type bottlenecks (e.g., suboptimal file system, etc.), and network-type bottlenecks (e.g., limited interconnect throughput, oversubscribed network topologies, or high intra-cluster latency). For instance, in a non-limiting example, a system bottleneck may be detected in one of the subscriber-specific compute architecture or the HPC environment corresponding to the subscriber-specific compute architecture that identifies GPU resources are remaining idle for a period of time exceeding a predetermined GPU idle duration threshold when data is being (e.g., slowly) transferred from a filesystem. Accordingly, the percent of potential value computed for the subscriber-specific compute architecture (e.g., HPC architecture data object generated for a target subscriber) or the corresponding HPC environment may reflect the detected system bottleneck (e.g., the percent of potential value of the reference compute architecture is 100, while the subscriber-specific compute architecture may be 82 based on the detected system bottleneck).

In other words, in some embodiments, the percent of potential value may be computed based on an assessment between the observed or projected performance of a subscriber-specific compute architecture and the theoretical maximum performance of a target reference compute architecture. The percent of potential value computation may account for the presence of any potential bottleneck detected within the subscriber-specific compute architecture that may adversely impact overall performance. It shall be understood that not all bottlenecks or contributing variables are explicitly described herein, and additional performance-limiting conditions may also influence the computed percent of potential value. Accordingly, the percent of potential value may indicate how closely the subscriber-specific compute architecture approaches the ideal operational performance of a reference compute system or architecture (e.g., if a filesystem sustains only 89% of its rated peak throughput, or an InfiniBand interconnect achieves only 92% of its theoretical maximum bandwidth to a GPU, the computed percent of potential value may reflect such performance degradations).

### 2.50 Generating and Surfacing Explainability Artifacts and Recommendations

S250, which includes generating and surfacing architecture explainability artifacts and recommendations, may function to generate and surface, via one or more computers, one or more explainability artifacts and one or more percent of potential improvement recommendations to a target subscriber. Explainability artifacts and recommendations, as generally referred to herein, may include textual content, graphical content, and/or any other suitable visualization that provides intelligent insights into a configuration of a subject subscriber-specific compute architecture (e.g., the HPC architecture data object generated for a target subscriber).

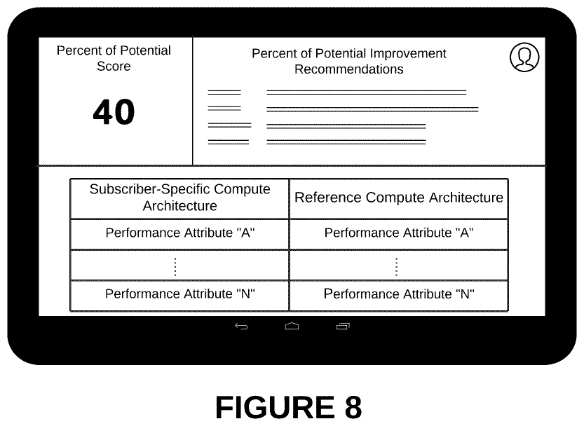

In one or more embodiments, based on receiving a high-performance computing architecture design request from a subscriber, the system or service implementing method 200 may function to design a subscriber-specific compute architecture for the subscriber and compute a percent of potential score for the subscriber-specific compute architecture in analogous ways as described above. Furthermore, in such embodiments, the system or service implementing method 200 may function to display the computed percent of potential score for the subscriber-specific compute architecture on a graphical user interface that is accessible by the subscriber, as shown generally by way of example in FIG. 8.

Additionally, or alternatively, in one or more embodiments, S250 may function to generate one or more percent of potential improvement recommendations for the subscriber-specific compute architecture. In such embodiments, each of the one or more percent of potential improvement recommendations generated for the subscriber-specific compute architecture may relate to mitigating a performance bottleneck, optimizing computational efficiency, increasing overall system performance, and/or the like. Stated another way, in one or more embodiments, each of the one or more percent of potential improvement recommendations, if implemented, may increase the percent of potential score associated with the subscriber-specific compute architecture. For instance, in a non-limiting example, one of the one or more percent of potential improvement recommendations generated for the subscriber-specific compute architecture may relate to transitioning the subscriber-specific compute architecture from an ethernet-based backend networking infrastructure to an InfiniBand-based backend networking infrastructure.

Additionally, or alternatively, in one or more embodiments, S250 may function to display each of the one or more percent of potential improvement recommendations generated for the subscriber-specific compute architecture on the graphical user interface, as shown generally by way of example in FIG. 8. Furthermore, in some embodiments, S250 may function to display a corresponding percent improvement contribution metric in association with each of the one or more percent of potential improvement recommendations generated for the subscriber-specific compute architecture. The percent improvement contribution metric, in such embodiments, may inform the subscriber of a system performance improvement effectiveness (or usefulness) of implementing such recommendation. Stated differently, the percent improvement contribution metric may inform the subscriber of the performance benefit or performance impact value of implementing a corresponding proposed percent of potential improvement recommendation.

Additionally, or alternatively, in one or more embodiments, S250 may function to generate and display, via the graphical user interface, interactive graphics or other visualizations that illustrate the differences in performance between the subscriber-specific compute architecture and the target reference compute architecture. These interactive graphics or visualizations may include comparative graphics showing bandwidth capacities, latency information, processing speed data, and any other type of performance efficacy metric. At least one technical advantage of displaying this type of information may include allowing subscribers to intuitively understand the performance disparity between the subscriber-specific compute architecture and the target reference compute architecture.

Additionally, or alternatively, in one or more embodiments, S250 may function to generate and display, via the graphical user interface, textual content, graphical content, interactive graphics, or the like that emphasize the identified deviations between the subscriber-specific compute architecture and the target reference compute architecture. Such textual content, graphical content, interactive graphics may be configured to illustrate where and how the system architectures differ, such as in backend networking infrastructure, GPU types, or any other hardware or software components. By surfacing these deviations to subscribers, subscribers can intuitively understand where their compute architecture diverges from the optimal or reference compute architecture.

In one or more embodiments, a system or service implementing method 200 may function to display, via a graphical user interface, a plurality of selectable normalization factors, wherein each selectable normalization factor of the plurality of selectable normalization factors corresponds to a distinct performance criterion for assessing the HPC architecture data object generated for the target subscriber relative to the reference HPC architecture data object. In such an embodiment, the system or service implementing method 200 may function to receive, via the graphical user interface, a user input selecting a selectable bandwidth normalization factor of the plurality of selectable normalization factors displayed on the graphical user interface. Accordingly, in response to receiving the user input selecting the selectable bandwidth normalization factor displayed on the graphical user interface, the system or service implementing method 200 may function to automatically compute a target normalized percent of potential score for the HPC architecture data object generated for the target subscriber based on assessing a (e.g., theoretical) maximum bandwidth capacity of the HPC architecture data object against a (e.g., theoretical) maximum bandwidth capacity of the reference HPC architecture data object.

Stated differently, in one or more embodiments, a system or service implementing method 200 may function to display, via a graphical user interface, a plurality of selectable normalization factors, wherein each selectable normalization factor of the plurality of selectable normalization factors corresponds to a distinct architecture performance assessment criterion. In such an embodiment, the system or service implementing method 200 may function to detect, via the graphical user interface, a sequence of one or more user inputs selecting each of the plurality of selectable normalization factors displayed on the graphical user interface. Accordingly, in response to the system or service implementing method 200 detecting the sequence of the one or more user inputs, the system or service implementing method 200 may function to simultaneously compute, in parallel, a respective normalized percent of potential score for each of the plurality of selectable normalization factors selected using the graphical user interface. It shall be recognized that, in some embodiments, each respective normalized percent of potential score may have been computed based on the distinct architecture performance assessment criterion of a respective selectable normalization factor of the plurality of selectable normalization factors for which that respective normalized percent of potential score corresponds.

In one or more embodiments, before computing a percent of potential score that indicates a degree of performance disparity between a target HPC architecture data object generated for a target subscriber and a target reference HPC architecture data object, the system or service implementing method 200 may function to compute a plurality of normalized percent of potential scores that collectively assess the target HPC architecture data object and the target reference HPC architecture data object across multiple distinct performance dimensions. Accordingly, in one or more embodiments, the system or service implementing method 200 may function to compute a composite percent of potential score based on a combination of the plurality of normalized percent of potential scores. The composite percent of potential score, in such an embodiment, may be used as the percent of potential score that indicates the degree of performance disparity between the HPC architecture data object and the reference HPC architecture data object.

It shall be recognized that, in some embodiments, the HPC architecture data object generated for a target subscriber may include a structured, machine-readable representation of a subscriber-specific compute architecture.

It shall be further recognized that, in some embodiments, the reference HPC architecture data object may include a structured, machine-readable representation of a reference compute architecture.

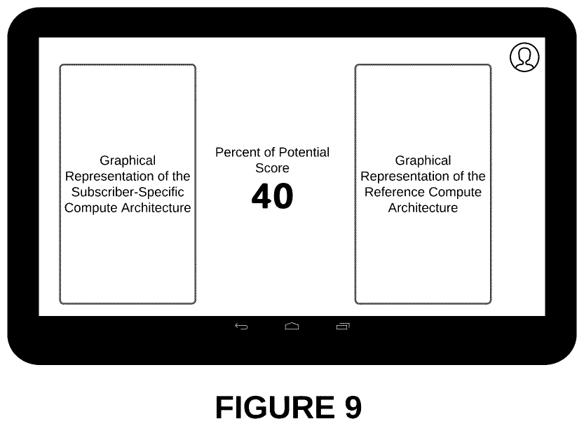

Turning to FIG. 9, in one or more embodiments, S250 may function to display, via a graphical user interface, a graphical representation of the subscriber-specific compute architecture, a graphical representation of the reference compute architecture, and a computed percent of potential score between the graphical representation of the subscriber-specific compute architecture and the graphical representation of the reference compute architecture. In such an embodiment, the graphical representation of the subscriber-specific compute architecture may be spatially separated from the graphical representation of the reference compute architecture by positioning the computed percent of potential score between the graphical representation of the subscriber-specific compute architecture and the graphical representation of the reference compute architecture on the graphical user interface.

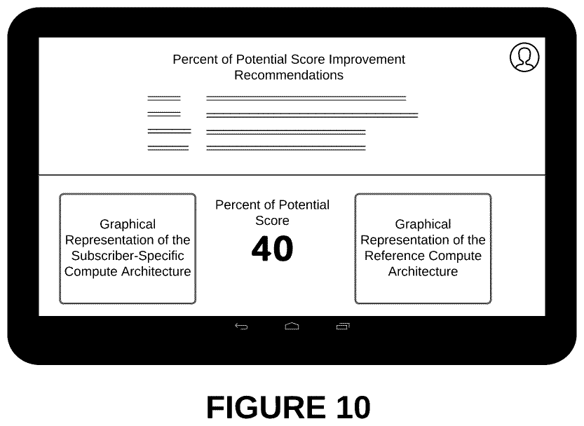

Turning to FIG. 10, one or more embodiments, the compute architecture optimization service may function to automatically generate a plurality of percent of potential score improvement recommendations for a target HPC architecture data object. Each percent of potential score improvement recommendation of the plurality of percent of potential score improvement recommendations, in one or more embodiments, may include a proposed modification to one or more hardware components or software components specified by the target HPC architecture data object. In such an embodiment, the compute architecture optimization service may function to display, via a graphical user interface, the plurality of percent of potential score improvement recommendations in association with a graphical representation of the target HPC architecture data object generated for the target subscriber and a graphical representation of a target reference HPC architecture data object.

In one or more embodiments, the compute architecture optimization service may function to detect an input selecting one of the plurality of percent of potential score improvement recommendations and, in turn, the compute architecture optimization service may function to automatically adapt (e.g., re-render), in real-time or near-real-time, the graphical representation of the target HPC architecture data object displayed on the graphical user interface to include the proposed modification that corresponds to the one of the plurality of percent of potential score improvement recommendations in response to detecting the input selecting the one of the plurality of percent of potential score improvement recommendations.

Additionally, or alternatively, in one or more embodiments, the compute architecture optimization service may function to detect an input selecting one of the plurality of percent of potential score improvement recommendations. Accordingly, in such an embodiment, in response to detecting the input selecting the one of the plurality of percent of potential score improvement recommendations, the graphical user interface may function to automatically scroll or automatically navigate within the graphical representation of the target HPC architecture data object to a portion of the graphical representation of the target HPC architecture data object that corresponds to the proposed modification specified by the one of the plurality of percent of potential score improvement recommendations. In other words, in some embodiments, the viewpoint or visual focus of the graphical user interface may be automatically adjusted to bring into view (e.g., focus) a target component (e.g., software component, hardware component, etc.) of the target HPC architecture data object—where the target component was not present in the original viewpoint or visual focus of the graphical user interface before the detection of the input selecting the one of the plurality of percent of potential score improvement recommendations-thereby enabling the user to observe and assess the specific area corresponding to the selected score performance improvement recommendation. It shall be recognized that, in some embodiments, the graphical user interface may be dynamically repositioned to display only components (e.g., select set of hardware components and software components) of the target HPC architecture data object that are directly associated with the selected recommendation, thereby reducing visual clutter and allowing the user to efficiently evaluate the proposed optimization in its proper architectural context.

Automatically scrolling, in some embodiments, may include programmatically adjusting the position of the viewport or display window within the graphical user interface to bring a specific portion of the graphical representation of the target HPC architecture data object into view. The adjustment may occur without direct user manipulation of scrollbars or navigation controls and may be triggered in response to detecting the user input selecting one of the plurality of percent of potential score improvement recommendations. In some embodiments, automatically scrolling may further include executing smooth scrolling animations, jump-to-location behavior, or directional panning to transition the user's visual focus toward the relevant architectural component, such as a compute node, interconnect, memory region, or storage device, associated with the selected recommendation.

Automatically navigating, in some embodiments, may include programmatically altering the navigational state or hierarchical focus of the graphical user interface to transition from a higher-level or abstracted view of the target HPC architecture data object to a more detailed or localized view corresponding to the selected performance improvement recommendation. This may include, for example, expanding a collapsed section of the architectural hierarchy, switching between tabbed interface panels, zooming into a specific subsystem or component group of the target HPC architecture data object, or re-centering the canvas to display a particular compute node, memory channel, or interconnect of the target HPC architecture data object. As with automatic scrolling, such navigation may occur without requiring direct user manipulation and may serve to guide the user toward the portion of the architectural component most relevant to the selected recommendation, thereby improving usability, comprehension, and efficiency in evaluating compute architecture optimization options.

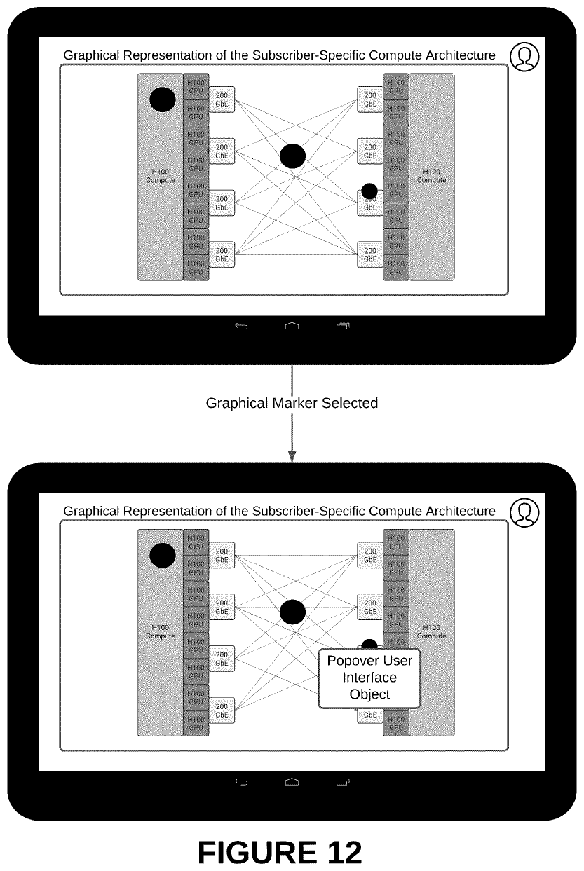

Turning to FIG. 12, in one or more embodiments, the compute architecture optimization service may function to display, via a graphical user interface, a graphical representation of a target HPC architecture data object. In such an embodiment, the compute architecture optimization service may function to automatically generate a corresponding graphical marker within the graphical representation of the target HPC architecture data object for each compute architecture deviation of a plurality of compute architecture deviations detected between the target HPC architecture data object and a target reference HPC architecture data object. In such an embodiment, the compute architecture optimization service may function to detect a user input selecting the corresponding graphical marker associated with a first compute architecture deviation of the plurality of compute architecture deviations. It shall be noted that, in such an embodiment, a user interface position of the corresponding graphical marker associated with the first compute architecture deviation within the graphical representation of the target HPC architecture data object may correspond to a location of a hardware or software component contributing to the first compute architecture deviation. Accordingly, in such an embodiment, in response to detecting the user input selecting the corresponding graphical marker associated with the first compute architecture deviation, the compute architecture optimization service may function to instantiate, via the graphical user interface, a popover user interface object that includes a natural language description of the first compute architecture deviation, a performance degradation factor attributed to the first compute architecture deviation, and one or more recommended compute architectural modifications to resolve the first compute architecture deviation.

### 3. Computer-Implemented Method and Computer Program Product

Embodiments of the system and/or method can include every combination and permutation of the various system components and the various method processes, wherein one or more instances of the method and/or processes described herein can be performed in real-time or near real-time, asynchronously (e.g., sequentially), concurrently (e.g., in parallel), or in any other suitable order by and/or using one or more instances of the systems, elements, and/or entities described herein.

The system and methods of the preferred embodiment and variations thereof can be embodied and/or implemented at least in part as a machine configured to receive a computer-readable medium storing computer-readable instructions. The instructions are preferably executed by computer-executable components preferably integrated with the system and one or more portions of the processors and/or the controllers. The computer-readable medium can be stored on any suitable computer-readable media such as RAMs, ROMs, flash memory, EEPROMs, optical devices (CD or DVD), hard drives, floppy drives, or any suitable device. The computer-executable component is preferably a general or application specific processor, but any suitable dedicated hardware or hardware/firmware combination device can alternatively or additionally execute the instructions.

In addition, in methods described herein where one or more steps are contingent upon one or more conditions having been met, it should be understood that the described method can be repeated in multiple repetitions so that over the course of the repetitions all of the conditions upon which steps in the method are contingent have been met in different repetitions of the method. For example, if a method requires performing a first step if a condition is satisfied, and a second step if the condition is not satisfied, then a person of ordinary skill would appreciate that the claimed steps are repeated until the condition has been both satisfied and not satisfied, in no particular order. Thus, a method described with one or more steps that are contingent upon one or more conditions having been met could be rewritten as a method that is repeated until each of the conditions described in the method has been met. This, however, is not required of system or computer readable medium claims where the system or computer readable medium contains instructions for performing the contingent operations based on the satisfaction of the corresponding one or more conditions and thus is capable of determining whether the contingency has or has not been satisfied without explicitly repeating steps of a method until all of the conditions upon which steps in the method are contingent have been met. A person having ordinary skill in the art would also understand that, similar to a method with contingent steps, a system or computer readable storage medium can repeat the steps of a method as many times as are needed to ensure that all of the contingent steps have been performed.

Although omitted for conciseness, the preferred embodiments include every combination and permutation of the implementations of the systems and methods described herein. Furthermore, each method step, process step, or the like described herein may be performed in real-time or near real-time. It shall be noted that “real-time” or “near real-time” as generally used herein may refer to generating an output or performing an action within strict time constraints. For example, in one or more embodiments, real-time may be understood to be instantaneous, on the order of milliseconds, or on the order of minutes. Of course, depending on the particular temporal nature of the system in which an embodiment is implemented, other appropriate timescales may be considered acceptable for real-time or near real-time processing.

As a person skilled in the art will recognize from the previous detailed description and from the figures and claims, modifications and changes can be made to the preferred embodiments of the invention without departing from the scope of this invention defined in the following claims.

We claim:

1. A computer-implemented method for real-time generation and performance optimization of high-performance computing (HPC) architectures, the computer-implemented method comprising:
at a compute architecture optimization service implemented by a distributed network of computers:
obtaining, via a graphical user interface, a set of compute architecture design parameters associated with a target subscriber, wherein the set of compute architecture design parameters include:
one or more distinct types of artificial intelligence (AI) compute tasks the target subscriber intends to execute within a HPC environment, and
a set of compute architecture design constraints specifying one or more immutable boundaries for controlling a compute architecture design space used by the compute architecture optimization service;
generating, by the distributed network of computers, a HPC architecture data object for the target subscriber that satisfies the set of compute architecture design parameters obtained via the graphical user interface, wherein generating the HPC architecture data object includes:
translating the set of compute architecture design parameters into a set of hardware components and a set of software components that are (i) collectively capable of supporting execution of the one or more distinct types of AI compute tasks and (ii) reside within the compute architecture design space formed according to the set of compute architecture design constraints, and
in response to generating the HPC architecture data object for the target subscriber:
executing, in real-time or near real-time by the distributed network of computers, one or more automated pairwise assessments between the HPC architecture data object generated for the target subscriber and a reference HPC architecture data object;
computing, in real-time or near real-time by the distributed network of computers, a percent of potential value that indicates a likely degree of computing performance disparity between the HPC architecture data object generated for the target subscriber and the reference HPC architecture data object based on pairwise assessment findings outputted by the one or more automated pairwise assessments; and
constructing, in the real-world, an optimal HPC environment for the target subscriber that:
improves a likely computing performance, when executing the one or more distinct types of AI compute tasks, by implementing the optimal HPC environment in lieu of a non-optimized HPC environment of a non-optimized HPC architecture data object, and
homologously corresponds to the HPC architecture data object when the percent of potential value satisfies a predetermined minimum score threshold value.

2. The computer-implemented method according to claim 1, wherein:
at least one of the one or more automated pairwise assessments detects that a first compute architecture deviation exists between the HPC architecture data object generated for the target subscriber and the reference HPC architecture data object,
the computer-implemented method further includes automatically retrieving, using the distributed network of computers, a performance degradation factor that corresponds to the first compute architecture deviation in response to querying a performance degradation repository using the first compute architecture deviation as a query parameter, and
the percent of potential value is computed by deducting the performance degradation factor that corresponds to the first compute architecture deviation from a service-default percent of potential value attributed to the reference HPC architecture data object.

3. The computer-implemented method according to claim 1, wherein:
the one or more automated pairwise assessments detect that a plurality of compute architecture deviations exist between the HPC architecture data object generated for the target subscriber and the reference HPC architecture data object,
the computer-implemented method further includes automatically retrieving, using the distributed network of computers, a respective performance degradation factor that corresponds to each compute architecture deviation of the plurality of compute architecture deviations in response to querying a performance degradation repository using the plurality of compute architecture deviations as query parameters, and
the percent of potential value is computed for the HPC architecture data object by deducting the respective performance degradation factor that corresponds to each compute architecture deviation of the plurality of compute architecture deviations from a service-default percent of potential value attributed to the reference HPC architecture data object.

4. The computer-implemented method according to claim 1, further comprising:
displaying, via the graphical user interface, a plurality of selectable normalization factors, wherein each selectable normalization factor of the plurality of selectable normalization factors corresponds to a distinct performance criterion for assessing the HPC architecture data object generated for the target subscriber relative to the reference HPC architecture data object;
receiving, via the graphical user interface, a user input selecting a selectable bandwidth normalization factor of the plurality of selectable normalization factors; and
in response to receiving the user input selecting the selectable bandwidth normalization factor displayed on the graphical user interface, automatically computing an additional percent of potential value for the HPC architecture data object generated for the target subscriber based on assessing a maximum bandwidth capacity of the HPC architecture data object against a maximum bandwidth capacity of the reference HPC architecture data object.

5. The computer-implemented method according to claim 1, further comprising:
displaying, via the graphical user interface, a plurality of selectable normalization factors, wherein each selectable normalization factor of the plurality of selectable normalization factors corresponds to a distinct architecture performance assessment criterion;
detecting, via the graphical user interface, a sequence of one or more user inputs selecting each of the plurality of selectable normalization factors displayed on the graphical user interface; and
in response to detecting the sequence of the one or more user inputs, simultaneously computing, in parallel, a respective normalized percent of potential value for each of the plurality of selectable normalization factors selected using the graphical user interface, wherein each respective normalized percent of potential value is computed based on the distinct architecture performance assessment criterion of a respective selectable normalization factor of the plurality of selectable normalization factors for which that respective normalized percent of potential value corresponds.

6. The computer-implemented method according to claim 1, wherein:
the percent of potential value computed for the HPC architecture data object does not satisfy the predetermined minimum score threshold value,
the computer-implemented method further includes:
in response to detecting the percent of potential value computed for the HPC architecture data object does not satisfy the predetermined minimum score threshold value:
providing the HPC architecture data object generated for the target subscriber and the reference HPC architecture data object as input to a machine learning model;
predicting, using the machine learning model, one or more percent of potential improvement recommendations for the HPC architecture data object based on the machine learning model assessing the HPC architecture data object generated for the target subscriber and the reference HPC architecture data object;
adapting the HPC architecture data object generated for the target subscriber to an adapted HPC architecture data object based on the one or more percent of potential improvement recommendations predicted by the machine learning model;
computing, in real-time or near real-time by the distributed network of computers, a second percent of potential value for the adapted HPC architecture data object indicating a degree of computing performance disparity between the adapted HPC architecture data object and the reference HPC architecture data object, wherein the second percent of potential value computed for the adapted HPC architecture data object satisfies the predetermined minimum score threshold value; and
constructing, in the real-world, an optimal HPC environment corresponding to the adapted HPC architecture data object for the target subscriber based on the second percent of potential value satisfying the predetermined minimum score threshold value, wherein the optimal HPC environment corresponding to the adapted HPC architecture data is constructed in lieu of a compute environment homologously corresponding to the HPC architecture data object generated for the target subscriber.

7. The computer-implemented method according to claim 6, wherein the one or more percent of potential improvement recommendations include:
a first percent of potential improvement recommendation that textually indicates replacing an ethernet-based networking configuration specified by the HPC architecture data object with an InfiniBand-based networking configuration,
a second percent of potential improvement recommendation that textually indicates updating a firmware version associated with one or more hardware components specified by the HPC architecture data object to a current firmware version or at least a more recent firmware version than the firmware version currently specified by the HPC architecture data object,
a third percent of potential improvement recommendation that textually indicates increasing a total number of compute nodes specified by the HPC architecture data object to a greater quantity of compute nodes than currently specified by the HPC architecture data object, and
a fourth percent of potential improvement recommendation that textually indicates replacing a first type of graphics processing unit (GPU) specified by the HPC architecture data object with a different GPU type.

8. The computer-implemented method according to claim 1, wherein:
the HPC architecture data object generated for the target subscriber includes a structured representation of a subscriber-specific compute architecture, the reference HPC architecture data object includes a structured representation of a reference compute architecture, and
the computer-implemented method further includes:
displaying, via the graphical user interface, a graphical representation of the subscriber-specific compute architecture;
displaying, via the graphical user interface, a graphical representation of the reference compute architecture; and
displaying, via the graphical user interface, the percent of potential value between the graphical representation of the subscriber-specific compute architecture and the graphical representation of the reference compute architecture, wherein the graphical representation of the subscriber-specific compute architecture is spatially separated from the graphical representation of the reference compute architecture.

9. The computer-implemented method according to claim 1, wherein executing the one or more automated pairwise assessments include:
assessing a maximum bandwidth capacity of the HPC architecture data object against a maximum bandwidth capacity of the reference HPC architecture data object,
assessing a total number of computing nodes included in the HPC architecture data object against a total number of computing nodes included in the reference HPC architecture data object,
assessing a backend networking infrastructure of the HPC architecture data object against a backend networking infrastructure of the reference HPC architecture data object,
assessing a type of graphics processing units included in the HPC architecture data object against a type of graphics processing units included in the reference HPC architecture data object, and
assessing a network latency profile of the HPC architecture data object against a network latency profile of the reference HPC architecture data object.

10. The computer-implemented method according to claim 1, wherein generating the HPC architecture data object for the target subscriber further includes:
instantiating, by the distributed network of computers, a data model based on a compute architecture schema provided by the compute architecture optimization service in response to translating the set of compute architecture design parameters into the set of hardware components and the set of software components, and
encoding, by the distributed network of computers, the data model to include the set of hardware components and the set of software components.

11. The computer-implemented method according to claim 1, wherein:
the percent of potential value satisfies the predetermined minimum score threshold value, and
constructing the optimal HPC environment for the target subscriber includes:
physically installing a plurality of computing nodes specified by the HPC architecture data object at a target real-world location or a target physical location, wherein each computing node of the plurality of computing nodes includes a plurality of graphics processing units (GPUs) and a plurality of central processing units (CPUs), and
physically connecting the plurality of computing nodes together using a plurality of physical networking components as specified by the HPC architecture data object.

12. The computer-implemented method according to claim 1, further comprising:
before computing the percent of potential value that indicates the likely degree of computing performance disparity between the HPC architecture data object generated for the target subscriber and the reference HPC architecture data object:
computing a plurality of normalized percent of potential values that collectively assess the HPC architecture data object and the reference HPC architecture data object across multiple distinct performance dimensions, and
computing a composite percent of potential value based on a combination of the plurality of normalized percent of potential values, wherein the composite percent of potential value is used as the percent of potential value indicating the likely degree of computing performance disparity between the HPC architecture data object generated for the target subscriber and the reference HPC architecture data object.

13. The computer-implemented method according to claim 1, wherein:
the compute architecture optimization service includes a plurality of predetermined reference HPC architecture data objects,
the computer-implemented method further includes before executing the one or more automated pairwise assessments:
detecting, via the graphical user interface, an input from a user selecting a target one of the plurality of predetermined reference HPC architecture data objects that corresponds to the reference HPC architecture data object, and
in response to detecting the input from the user selecting the target one of the plurality of predetermined reference HPC architecture data objects, automatically commencing the one or more automated pairwise assessments.

14. The computer-implemented method according to claim 1, wherein:
the compute architecture optimization service automatically elects the reference HPC architecture data object to be assessed against the HPC architecture data object, and
in response to the compute architecture optimization service automatically electing the reference HPC architecture data object, automatically commencing the one or more automated pairwise assessments.

15. A computer-program product comprising a non-transitory machine-readable storage medium storing computer instructions that, when executed by one or more processors, perform operations comprising:
at a compute architecture optimization service:
obtaining, via a graphical user interface, a set of compute architecture design parameters associated with a target subscriber, wherein the set of compute architecture design parameters include:
one or more distinct types of artificial intelligence (AI) compute tasks the target subscriber intends to execute within a HPC environment, and
a set of compute architecture design constraints specifying one or more immutable boundaries for controlling a compute architecture design space used by the compute architecture optimization service;
generating, by the one or more processors, a HPC architecture data object for the target subscriber that satisfies the set of compute architecture design parameters obtained via the graphical user interface, wherein generating the HPC architecture data object includes:
translating the set of compute architecture design parameters into a set of hardware components and a set of software components that are (i) collectively capable of supporting execution of the one or more distinct types of AI compute tasks and (ii) reside within the compute architecture design space formed according to the set of compute architecture design constraints, and
in response to generating the HPC architecture data object for the target subscriber:
executing, in real-time or near real-time by the one or more processors, one or more automated pairwise assessments between the HPC architecture data object generated for the target subscriber and a reference HPC architecture data object;
computing, in real-time or near real-time by the one or more processors, a percent of potential value that indicates a degree of performance disparity between the HPC architecture data object generated for the target subscriber and the reference HPC architecture data object based on pairwise assessment findings outputted by the one or more automated pairwise assessments; and
constructing, in the real-world, an optimal HPC environment corresponding to the HPC architecture data object when the percent of potential value satisfies a predetermined minimum score threshold value.

16. The computer-program product according to claim 15, wherein the computer instructions, when executed by the one or more processors, perform operations further comprising:
automatically generating a plurality of percent of potential value improvement recommendations for the HPC architecture data object, wherein each percent of potential value improvement recommendation of the plurality of percent of potential value improvement recommendations includes a proposed modification to one or more hardware components or software components specified by the HPC architecture data object;
displaying, via the graphical user interface, the plurality of percent of potential value improvement recommendations in association with a graphical representation of the HPC architecture data object generated for the target subscriber and a graphical representation of the reference HPC architecture data object,
detecting an input selecting one of the plurality of percent of potential value improvement recommendations, and
in response to detecting the input selecting the one of the plurality of percent of potential value improvement recommendations, automatically adapting the graphical representation of the HPC architecture data object displayed on the graphical user interface to include the proposed modification that corresponds to the one of the plurality of percent of potential value improvement recommendations.

17. The computer-program product according to claim 15, wherein the computer instructions, when executed by the one or more processors, perform operations further comprising:
automatically generating a plurality of percent of potential value improvement recommendations for the HPC architecture data object, wherein each percent of potential value improvement recommendation of the plurality of percent of potential value improvement recommendations includes a proposed modification to one or more hardware components or software components specified by the HPC architecture data object;
displaying, via the graphical user interface, the plurality of percent of potential value improvement recommendations in association with a graphical representation of the HPC architecture data object generated for the target subscriber and a graphical representation of the reference HPC architecture data object,
detecting an input selecting one of the plurality of percent of potential value improvement recommendations, and
in response to detecting the input selecting the one of the plurality of percent of potential value improvement recommendations:
automatically scrolling or automatically navigating within the graphical representation of the HPC architecture data object to a portion of the graphical representation of the HPC architecture data object that corresponds to the proposed modification specified by the one of the plurality of percent of potential value improvement recommendations.

18. The computer-program product according to claim 15, wherein the computer instructions, when executed by the one or more processors, perform operations further comprising:
detecting, during the execution of the one or more automated pairwise assessments, a plurality of compute architecture deviations between the HPC architecture data object generated for the target subscriber and the reference HPC architecture data object;
attributing a corresponding performance degradation factor to each compute architecture deviation of the plurality of compute architecture deviations; and
displaying, via the graphical user interface, a data table that includes the plurality of compute architecture deviations in association with their respective corresponding performance degradation factor.

19. The computer-program product according to claim 18, wherein the computer instructions, when executed by the one or more processors, perform operations further comprising:
displaying, via the graphical user interface, a graphical representation of the HPC architecture data object;
automatically generating, for each compute architecture deviation of the plurality of compute architecture deviations, a corresponding graphical marker within the graphical representation of the HPC architecture data object;
detecting a user input selecting the corresponding graphical marker associated with a first compute architecture deviation of the plurality of compute architecture deviations, wherein a user interface position of the corresponding graphical marker associated with the first compute architecture deviation within the graphical representation of the HPC architecture data object corresponds to a location of a hardware or software component of the HPC architecture data object contributing to the first compute architecture deviation; and
in response to detecting the user input selecting the corresponding graphical marker associated with the first compute architecture deviation, instantiating, via the graphical user interface, a popover user interface object that includes a natural language description of the first compute architecture deviation, the corresponding performance degradation factor attributed to the first compute architecture deviation, and one or more recommended compute architectural modifications to resolve the first compute architecture deviation.

20. A computer-implemented system comprising:
one or more processors;
a memory;
a computer-readable medium operably coupled to the one or more processors, the computer-readable medium having computer-readable instructions stored thereon that, when executed by the one or more processors, cause a computing device to perform operations comprising:
at a compute architecture optimization service:
obtaining, via a graphical user interface, a set of compute architecture design parameters associated with a target subscriber, wherein the set of compute architecture design parameters include:
one or more distinct types of artificial intelligence (AI) compute tasks the target subscriber intends to execute within a HPC environment, and
a set of compute architecture design constraints specifying one or more immutable boundaries for controlling a compute architecture design space used by the compute architecture optimization service;
generating, by the one or more processors, a HPC architecture data object for the target subscriber that satisfies the set of compute architecture design parameters obtained via the graphical user interface, wherein generating the HPC architecture data object includes:
translating the set of compute architecture design parameters into a set of hardware components and a set of software components that are (i) collectively capable of supporting execution of the one or more distinct types of AI compute tasks and (ii) reside within the compute architecture design space formed according to the set of compute architecture design constraints, and
in response to generating the HPC architecture data object for the target subscriber:
executing, in real-time or near real-time by the one or more processors, one or more automated pairwise assessments between the HPC architecture data object generated for the target subscriber and a reference HPC architecture data object;
computing, in real-time or near real-time by the one or more processors, a percent of potential value for the HPC architecture data object that indicates a degree of computing performance disparity between the HPC architecture data object generated for the target subscriber and the reference HPC architecture data object based on pairwise assessment findings outputted by the one or more automated pairwise assessments; and
constructing, in the physical world, an optimal HPC environment corresponding to the HPC architecture data object when the percent of potential value satisfies a predetermined minimum score threshold value.
